(19) United States
(12) Patent Application Publication
(10) Pub. No.: US 2025/0308560 A1
(43) Pub. Date: Oct. 2, 2025

(54) INTEGRATED CIRCUIT DEVICE AND ELECTRONIC SYSTEM INCLUDING THE SAME

(71) Applicant: SAMSUNG ELECTRONICS CO., LTD., Suwon-si (KR)

(72) Inventors: Kangoh Yun, Suwon-si (KR); Youngrok Kim, Suwon-si (KR); Dongjin Lee, Suwon-si (KR); Jaeduk Lee, Suwon-si (KR)

(21) Appl. No.: 18/999,967

(22) Filed: Dec. 23, 2024

(30) Foreign Application Priority Data
Apr. 1, 2024 (KR) 10-2024-0044237

(51) Int. Cl. G11C 5/06; G11C 16/04; H01L 25/07; H10B 41/10; H10B 41/35; H10B 41/41; H10B 43/10; H10B 43/35; H10B 43/40; H10B 80/00

(52) U.S. Cl. CPC G11C 5/06; G11C 16/0483; H01L 25/074; H10B 41/10; H10B 41/35; H10B 41/41; H10B 43/10; H10B 43/35; H10B 43/40; H10B 80/00; H01L 2225/06506

(57) ABSTRACT

An example integrated circuit device includes a substrate, a gate structure, and a multilayer wiring structure. The substrate includes an active region and source and drain doped regions located within the active region and spaced apart from each other in a first horizontal direction. The gate structure is disposed between the source and drain doped regions on the substrate and extends in a second horizontal direction intersecting the first horizontal direction. The multilayer wiring structure includes a source and drain contact connected to the source and drain doped regions, a gate contact connected to the gate structure, a first wiring layer connected to an upper portion of the source and drain contact, and a second wiring layer disposed between the source and drain contact and the gate contact and spaced apart from the first wiring layer.

### CROSS-REFERENCE TO RELATED APPLICATION

This application claims priority under 35 U.S.C. § 119 to Korean Patent Application No. 10-2024-0044237, filed on Apr. 1, 2024, in the Korean Intellectual Property Office, the disclosure of which is incorporated by reference herein in its entirety.

### BACKGROUND

Consumers demand integrated circuit memory devices with high performance, small size, and low price. Therefore, to implement an integrated circuit device with high integration, an integrated circuit device including a 3-dimensional non-volatile memory device in which a plurality of memory cells are arranged in a vertical direction and an electronic system including the integrated circuit device have been proposed.

### SUMMARY

The present disclosure relates to an integrated circuit device with a high degree of integration and improved performance and reliability, and an electronic system with a high degree of integration and improved performance and reliability.

In addition, the technical goals to be achieved by the present disclosure are not limited to the technical goals mentioned above, and other technical goals may be clearly understood by one of ordinary skill in the art from the following descriptions.

In general, according to some aspects, an integrated circuit device includes a substrate including an active region and source and drain doped regions located within the active region and spaced apart from each other in a first horizontal direction, a gate structure disposed between the source and drain doped regions spaced apart from each other on the substrate and extending in a second horizontal direction intersecting the first horizontal direction, and a multilayer wiring structure including a source and drain contact connected to the source and drain doped regions, a gate contact connected to the gate structure, a first wiring layer connected to an upper portion of the source and drain contact, and a second wiring layer disposed to be spaced apart from the first wiring layer between the source and drain contact and the gate contact, wherein a length of the second wiring layer in a vertical direction is greater than a length of the first wiring layer in the vertical direction.

In general, according to some aspects, an integrated circuit device includes a substrate including a device isolation region, an active region located within the device isolation region, low-concentration source and drain doped regions located within the active region and spaced apart from one another in a first horizontal direction, and high-concentration source and drain doped regions located inside the low-concentration source and drain doped regions and more densely doped than the low-concentration source and drain doped regions, a gate structure disposed between the low-concentration source and drain doped regions spaced apart from each other on the substrate and extending in a second horizontal direction perpendicular to the first horizontal direction, an etch stop film extending in the first horizontal direction over the substrate, and a multilayer wiring structure including a source and drain contact connected to a high-concentration source and drain doped region, a gate contact connected to the gate structure, a first wiring layer connected to an upper end of the source and drain contact, a second wiring layer disposed at a location vertically overlapping a portion of a low-concentration source and drain doped region, a first peripheral circuit contact connected to an upper end of the second wiring layer, a third wiring layer connected to an upper end of the gate contact, a second peripheral circuit contact connected to an upper end of the third wiring layer, and a fourth wiring layer connected to an upper end of the first peripheral circuit contact and an upper end of the second peripheral circuit contact, wherein a length of the second wiring layer in a vertical direction is greater than a length of the first wiring layer in the vertical direction.

In general, according to some aspects, an electronic system includes a main substrate, a cell stacked structure including a peripheral circuit structure and a cell array structure, wherein the cell array structure includes a plurality of gate electrodes and a plurality of insulation layers, which overlap the peripheral circuit structure in a vertical direction and are alternately stacked, and has a step-like shape, and a controller electrically connected to the integrated circuit device on the main substrate, wherein the peripheral circuit structure includes a substrate including a device isolation region, an active region located within the device isolation region, low-concentration source and drain doped regions located within the active region and spaced apart from one another in a first horizontal direction, and high-concentration source and drain doped regions located inside the low-concentration source and drain doped regions and more densely doped than the low-concentration source and drain doped regions, a gate structure disposed between the low-concentration source and drain doped regions spaced apart from each other on the substrate and extending in a second horizontal direction perpendicular to the first horizontal direction, an etch stop film extending in the first horizontal direction over the substrate, and a multilayer wiring structure including a source and drain contact connected to a high-concentration source and drain doped region, a gate contact connected to the gate structure, a first wiring layer connected to an upper end of the source and drain contact, a second wiring layer connected to the etch stop film, a first peripheral circuit contact connected to an upper end of the second wiring layer, a third wiring layer connected to an upper end of the gate contact, a second peripheral circuit contact connected to an upper end of the third wiring layer, and a fourth wiring layer connected to an upper end of the first peripheral circuit contact and an upper end of the second peripheral circuit contact, anda length of the second wiring layer in the vertical direction is greater than a length of the first wiring layer in the vertical direction.

### BRIEF DESCRIPTION OF THE DRAWINGS

Implementations of the present disclosure will be more clearly understood from the following detailed description taken in conjunction with the accompanying drawings.

FIG. 1 is a block diagram showing an example of an integrated circuit device.

FIG. 2 is a schematic perspective view of an example of an integrated circuit device.

FIG. 3 is a schematic perspective view of an example of an integrated circuit device.

FIG. 4 is an equivalent circuit diagram of an example of a memory cell array of an integrated circuit device.

FIG. 5 is a layout diagram showing an example of an integrated circuit device.

FIG. 6 is an example cross-sectional view taken along a line X1-X1′ of FIG. 5, and FIG. 7 is an example enlarged view of a region “CX1” of FIG. 6.

FIG. 8 is a cross-sectional view of an example of an integrated circuit device, which corresponds to the cross-sectional view of FIG. 6, and FIG. 9 is an example enlarged view of a region “CX2” of FIG. 8.

FIG. 10 is a layout diagram showing an example of an integrated circuit device.

FIG. 11 is an example cross-sectional view taken along a line X2-X2′ of FIG. 10.

FIGS. 12 to 17 are example cross-sectional views sequentially showing some of operations of the process of manufacturing an integrated circuit device shown in FIGS. 5 to 7.

FIGS. 18 and 19 are example diagrams each schematically showing an electronic system including an integrated circuit element.

FIG. 20 is a schematic perspective view of an example of an electronic system including an integrated circuit element.

FIG. 21 is a schematic perspective view of an example of an electronic system including an integrated circuit device.

FIG. 22 is a schematic cross-sectional view of an example of a semiconductor package.

### DETAILED DESCRIPTION

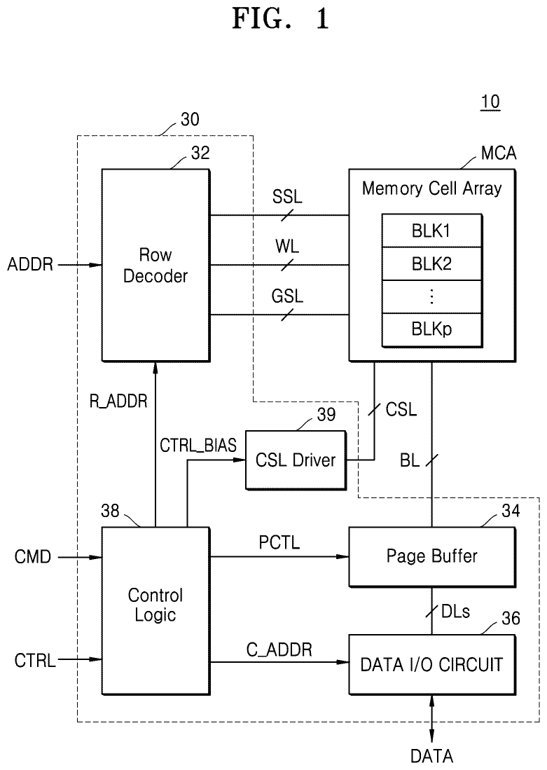

FIG. 1 is a block diagram showing an example of an integrated circuit device 10.

In detail, the integrated circuit device 10 may include a memory cell array 20 and a peripheral circuit 30. The memory cell array 20 may be controlled by the peripheral circuit 30. The memory cell array 20 may include a plurality of memory cell blocks BLK1, BLK2, . . . , and BLKp. The memory cell blocks BLK1, BLK2, . . . , and BLKp may each include a plurality of memory cells. The memory cell blocks BLK1, BLK2, . . . , and BLKp may be connected to the peripheral circuit 30 through a bit line BL, a word line WL, a string select line SSL, and a ground select line GSL.

The peripheral circuit 30 may include a row decoder 32, a page buffer 34, a data input/output circuit 36, a control logic 38, and a common source line driver 39. The peripheral circuit 30 may further include various circuits like a voltage generating circuit for generating various voltages needed for the operation of the integrated circuit device 10, an error correction circuit for correcting errors in data read from the memory cell array 20, and an input/output interface.

According to some implementations, each component constituting the peripheral circuit 30 may include a plurality of transistors, e.g., MOS transistors. According to some implementations, each component constituting the peripheral circuit 30 may include a plurality of transistors, e.g., high voltage transistors. According to some implementations, high voltage transistors may refer to transistors having a breakdown voltage from about 5 to about 10V or a breakdown voltage higher than 10V.

The memory cell array 20 may be connected to the row decoder 32 through the word line WL, the string select line SSL, and the ground select line GSL and may be connected to the page buffer 34 through the bit line BL. In the memory cell array 20, memory cells included in the memory cell blocks BLK1, BLK2, . . . , and BLKp may be flash memory cells. The memory cell array 20 may include a 3-dimensional memory cell array. The 3-dimensional memory cell array may include a plurality of NAND strings, and the plurality of NAND strings may each include a plurality of memory cells connected to a plurality of word lines WL vertically stacked.

The peripheral circuit 30 may receive an address ADDR, a command CMD, and a control signal CTRL from a device outside the integrated circuit device 10 and may transmit and receive data DATA to and from the device outside the integrated circuit device 10. The row decoder 32 may select at least one of the plurality of memory cell blocks BLK1, BLK2, . . . , and BLKp in response to an address ADDR from the outside and select the word line WL, the string select line SSL, and the ground select line GSL corresponding to the selected memory cell block. The row decoder 32 may transmit a voltage for performing a memory operation to the word line WL corresponding to the selected memory cell block.

The page buffer 34 may be connected to the memory cell array 20 through the bit line BL. The page buffer 34 may operate as a write driver during a program operation and apply a voltage according to the data DATA to be stored in the memory cell array 20 to the bit line BL and may operate as a sense amplifier during a read operation and sense the data DATA stored in the memory cell array 20. The page buffer 34 may operate according to a control signal PCTL provided from the control logic 38.

The data input/output circuit 36 may be connected to the page buffer 34 through a plurality of data lines DLs. During a program operation, the data input/output circuit 36 may receive the data DATA from a memory controller and provide the data DATA to be programmed to the page buffer 34 based on a column address C_ADDR provided from the control logic 38. The data input/output circuit 36 may provide the data DATA to be read stored in the page buffer 34 to the memory controller based on the column address C_ADDR provided from the control logic 38 during a read operation.

The data input/output circuit 36 may transmit an address or a command input thereto to the control logic 38 or the row decoder 32. The peripheral circuit 30 may further include an electrostatic discharge (ESD) circuit and a pull-up/pull-down driver.

The control logic 38 may receive a command CMD and a control signal CTRL from the memory controller. The control logic 38 may provide a row address R_ADDR to the row decoder 32 and provide the column address C_ADDR to the data input/output circuit 36. The control logic 38 may generate various internal control signals used in the integrated circuit device 10 in response to the control signal CTRL. For example, the control logic 38 may adjust the level of a voltage provided to the word line WL and the bit line BL when a memory operation like a program operation or an erase operation is performed.

The common source line driver 39 may be connected to the memory cell array 20 through a common source line CSL. The common source line driver 39 may apply a common source voltage (e.g., power voltage) or a ground voltage to the common source line CSL based on a bias signal CTRL_BIAS of the control logic 38.

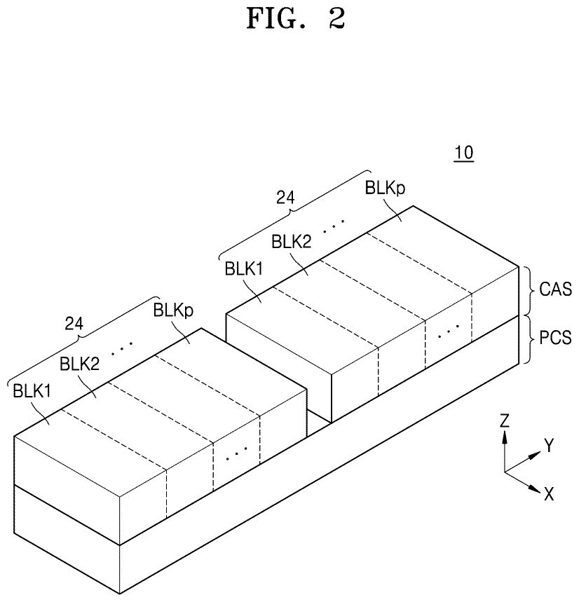

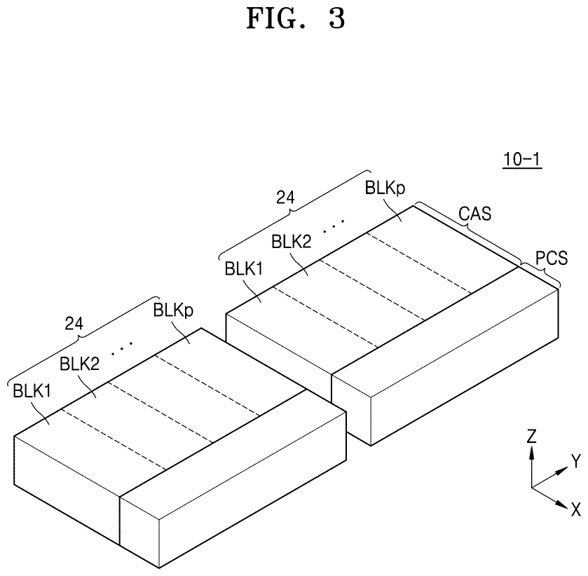

FIG. 2 is a schematic perspective view of an example of the integrated circuit device 10.

In detail, the integrated circuit device 10 may include a cell array structure CAS and a peripheral circuit structure PCS that overlap each other in the vertical direction (Z direction). The horizontal direction (X direction) may be referred to as a first horizontal direction. The horizontal direction orthogonal to the first horizontal direction (X direction) and the vertical direction (Z direction) may be referred to as a second horizontal direction (Y direction). The cell array structure CAS may include the memory cell array 20 of FIG. 1.

According to some implementations, the peripheral circuit structure PCS may include a plurality of transistors, e.g., MOS transistors. According to some implementations, the peripheral circuit structure PCS may include a plurality of transistors, e.g., high voltage transistors. According to some implementations, high voltage transistors may refer to transistors having a breakdown voltage from about 5 to about 10V or a breakdown voltage higher than 10V. The peripheral circuit structure PCS may include the peripheral circuit 30 of FIG. 1.

The cell array structure CAS may include a plurality of tiles 24. The tiles 24 may include a plurality of memory cell blocks BLK1, BLK2, . . . , and BLKp. The memory cell blocks BLK1, BLK2, . . . , and BLKp may each include 3-dimensionally arranged memory cells.

FIG. 3 is a schematic perspective view of an example of an integrated circuit device 10-1.

In detail, the integrated circuit device 10-1 may include the cell array structure CAS and the peripheral circuit structure PCS arranged in the first horizontal direction (X direction). The peripheral circuit structure PCS may be arranged in the first horizontal direction (X direction) differently from that shown in FIG. 3.

The cell array structure CAS may include the memory cell array 20 of FIG. 1. According to some implementations, the peripheral circuit structure PCS may include a plurality of transistors as described with reference to FIG. 2, e.g., MOS transistors or high voltage transistors. The peripheral circuit structure PCS may include the peripheral circuit 30 of FIG. 1.

The cell array structure CAS may include a plurality of tiles 24 like in FIG. 2. The tiles 24 may include a plurality of memory cell blocks BLK1, BLK2, . . . , and BLKp. The memory cell blocks BLK1, BLK2, . . . , and BLKp may each include 3-dimensionally arranged memory cells.

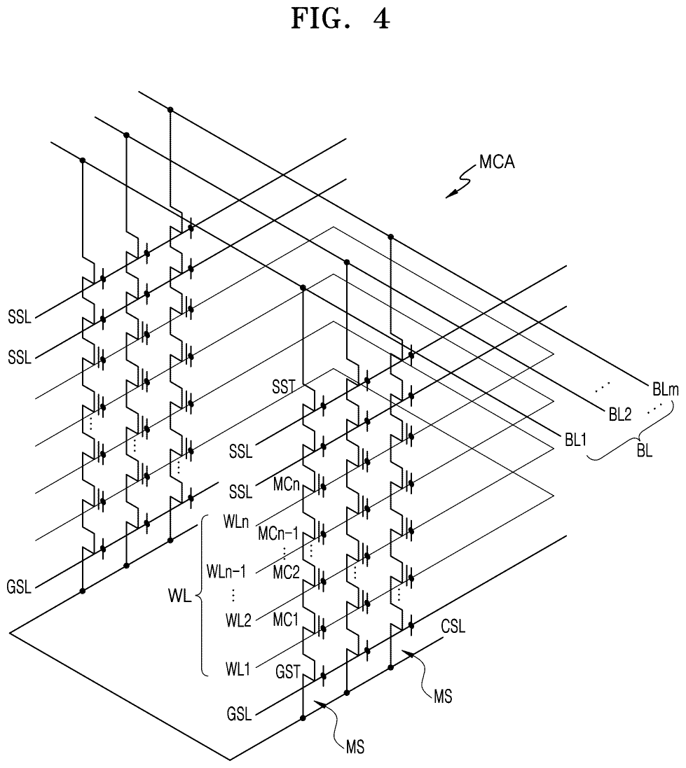

FIG. 4 is an equivalent circuit diagram of an example of a memory cell array MCA of an integrated circuit device.

In detail, FIG. 4 illustrates an equivalent circuit diagram of a vertical NAND flash memory device having a vertical channel structure. The memory cell blocks BLK1, BLK2, . . . , and BLKp of FIGS. 1 to 3 may each include the memory cell array MCA having the circuit configuration illustrated in FIG. 4.

A memory cell array MCA may include a plurality of memory cell strings MS. The memory cell array MCA may include a plurality of bit lines BL or BL1, BL2, . . . , and BLm, a plurality of word lines WL or WL1, WL2, . . . , WLn-1, and WLn, at least one string select line SSL, at least one ground select line GSL, and a common source line CSL.

The plurality of memory cell strings MS may be formed between the plurality of bit lines BL and the common source line CSL. Although FIG. 4 shows a case in which the memory cell strings MS each include one ground select line GSL and two string select lines SSL, the present disclosure is not limited thereto. For example, the memory cell strings MS may each include one string select line SSL.

The memory cell strings MS may each include the string select transistor SST, the ground select transistor GST, and a plurality of memory cell transistors MC1, MC2, . . . , MCn-1, and MCn. A drain region of the string select transistor SST may be connected to the bit lines BL, and a source region of the ground select transistor GST may be connected to the common source line CSL. The common source line CSL may be a region in which source regions of a plurality of ground select transistors GST are connected in common.

The string select transistor SST may be connected to the string select line SSL, and the ground select transistor GST may be connected to the ground select line GSL. The memory cell transistors MC1, MC2, . . . , MCn-1, and MCn may be connected to the word lines WL, respectively.

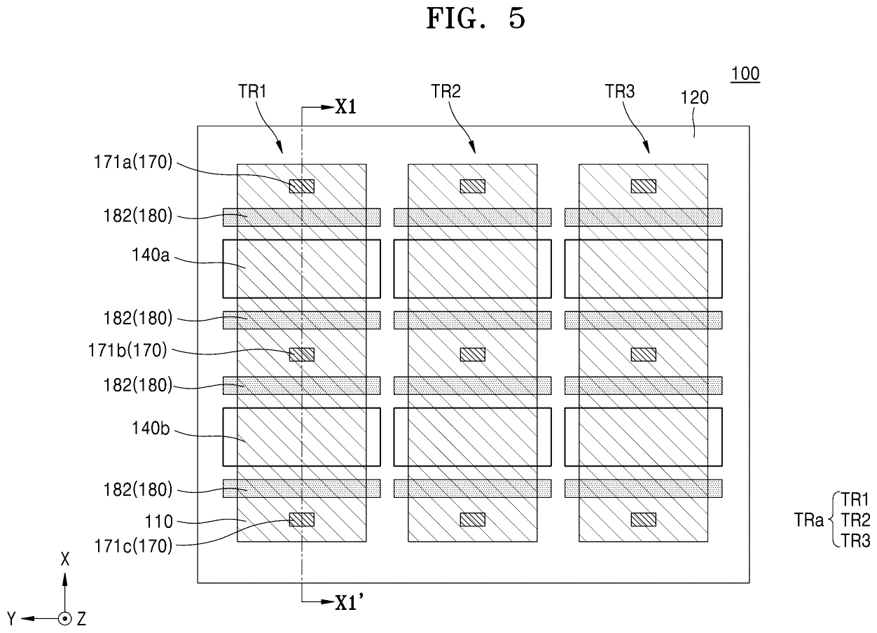

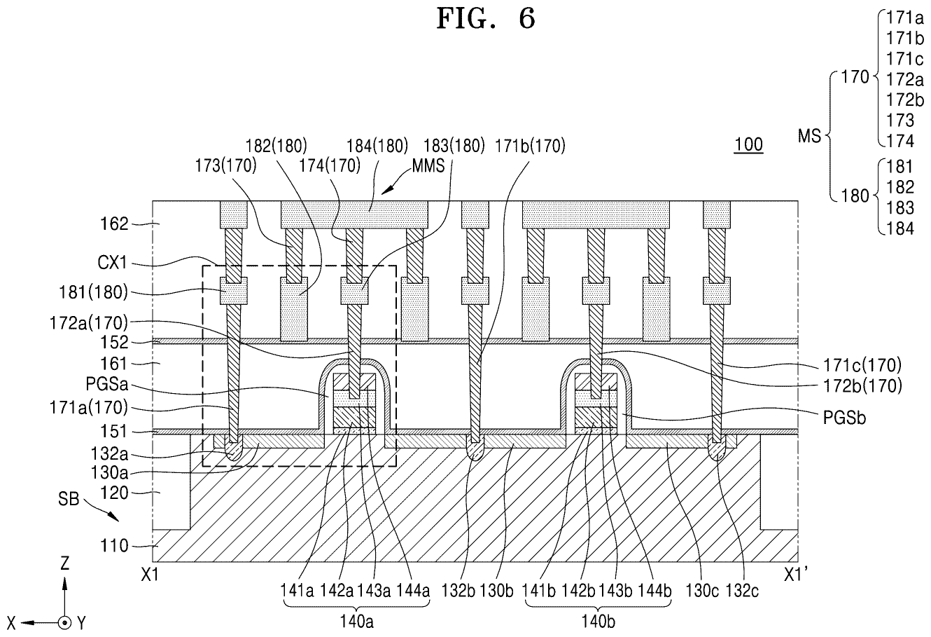

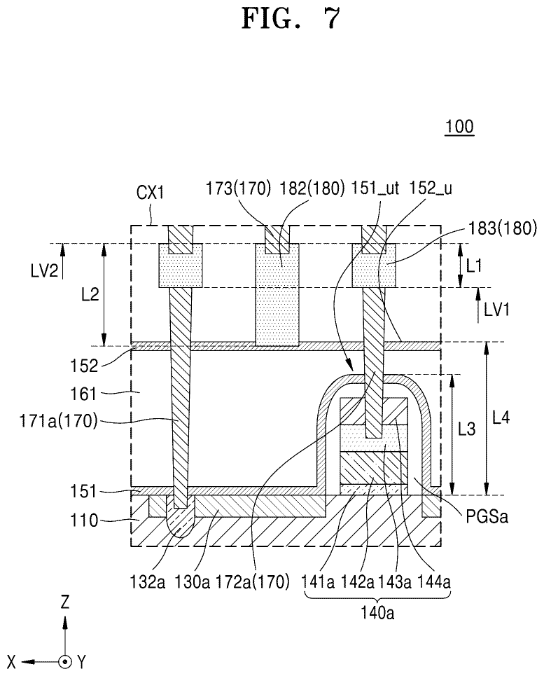

FIG. 5 is a layout diagram showing an example of an integrated circuit device 100. FIG. 6 is an example cross-sectional view taken along a line X1-X1′ of FIG. 5, and FIG. 7 is an example enlarged view of a region “CX1” of FIG. 6.

Referring to FIGS. 5, 6, and 7, the integrated circuit device 100 may include a substrate SB, a pass transistor structure TRa, a first gate structure 140a, a second gate structure 140b, and a multilayer wiring structure MMS. The integrated circuit device 100 may be disposed in the peripheral circuit structure PCS described with reference to FIG. 3.

The substrate SB may include a semiconductor substrate. For example, the substrate SB may include a semiconductor material, e.g., a group IV semiconductor, a group III-V compound semiconductor, or a group II-VI oxide semiconductor. For example, a group IV semiconductor may include silicon (Si), germanium (Ge), or silicon-germanium (SiGe). The substrate SB may be provided as a bulk wafer or an epitaxial layer. According to some implementations, the substrate SB may include a silicon-on-insulator (SOI) substrate or a germanium-on-insulator (GeOI) substrate. The substrate SB may include an active region 110 and a device isolation layer 120. The active region 110 may be defined on the substrate SB by the device isolation layer 120. In a plan view, the active region 110 may have a rectangular shape in which the length in the first horizontal direction (X direction) is greater than the length in the second horizontal direction (Y direction).

The first gate structure 140a and the second gate structure 140b may each intersect the active region 110 on the substrate SB. The first gate structure 140a and the second gate structure 140b may be arranged to be spaced apart from each other in a horizontal direction on the active region 110. Here, in FIG. 3, the horizontal direction in which the first gate structure 140a and the second gate structure 140b are spaced apart from each other may be defined as the first horizontal direction (X direction). The first gate structure 140a and the second gate structure 140b may each be formed to extend in a horizontal direction on the active region 110. Here, the horizontal direction in which the first gate structure 140a and the second gate structure 140b extend may be defined as the second horizontal direction (Y direction). The first gate structure 140a and the second gate structure 140b may extend lengthwise in the second horizontal direction (Y direction). Here, the first horizontal direction (X direction) and the second horizontal direction (Y direction) are directions that intersect each other. As a direction intersecting the first horizontal direction (X direction) and the second horizontal direction (Y direction), the direction perpendicular to the top surface of the substrate SB may be defined as the vertical direction (Z direction). According to some implementations, in a plan view, the first gate structure 140a and the second gate structure 140b may protrude from edges of the active region 110 and extend to overlap portions of the device isolation layer 120.

A collection of the active region 110, the first gate structure 140a crossing the active region 110, and the second gate structure 140b may constitute the pass transistor structure TRa. The pass transistor structure TRa may include a first pass transistor TR1, a second pass transistor TR2, and a third pass transistor TR3. The first pass transistor TR1, the second pass transistor TR2, and the third pass transistor TR3 may be arranged to be spaced apart from one another other in the second horizontal direction (Y direction).

In addition to the active region 110 and device isolation layer 120, the substrate SB may include a plurality of low-concentration source and drain regions 130a, 130b, and 130c and a plurality of high-concentration source and drain regions 132a, 132b, and 132c. The plurality of low-concentration source and drain regions 130a, 130b, and 130c may include a first low-concentration source and drain region 130a, a second low-concentration source and drain region 130b, and a third low-concentration source and drain region 130c, and the plurality of high-concentration source and drain regions 132a, 132b, and 132c may include a first high-concentration source and drain region 132a, a second high-concentration source and drain region 132b, and a third high-concentration source and drain region 132c.

The plurality of low-concentration source and drain regions 130a, 130b, and 130c and the plurality of high-concentration source and drain regions 132a, 132b, and 132c may be regions doped with impurities of a conductivity type opposite to that of the active region 110. According to some implementations, the active region 110 may be a region doped with a p-type impurity such as boron (B), indium (In), gallium (Ga), or aluminum (Al), whereas the plurality of low-concentration source and drain regions 130a, 130b, and 130c and the plurality of high-concentration source and drain regions 132a, 132b, and 132c may be regions doped with n-type impurities such as phosphorus (P), arsenic (As), bismuth (Bi), or antimony (Sb).

The plurality of low-concentration source and drain regions 130a, 130b, and 130c may be arranged in a gate-adjacent region adjacent to a plurality of gate structures 140a and 140b, that is, the first gate structure 140a and the second gate structure 140b. The plurality of low-concentration source and drain regions 130a, 130b, and 130c may be referred to as lightly doped drain (LDD) regions. The first low-concentration source and drain region 130a and the second low-concentration source and drain region 130b may be arranged on both sides of the first gate structure 140a in the first horizontal direction (X direction), and the second low-concentration source and drain region 130b and the third low-concentration source and drain region 130c may be arranged on both sides of the second gate structure 140b in the first horizontal direction (X direction).

Although FIG. 6 shows that the plurality of low-concentration source and drain regions 130a, 130b, and 130c and the plurality of gate structures 140a and 140b do not overlap each other in the vertical direction (Z direction), according to some implementations, portions of the plurality of low-concentration source and drain regions 130a, 130b, and 130c may overlap the plurality of gate structures 140a and 140b in the vertical direction (Z direction).

The plurality of high-concentration source and drain regions 132a, 132b, and 132c may be positioned to be surrounded by the plurality of low-concentration source and drain regions 130a, 130b, and 130c, respectively. In other words, the first high-concentration source and drain region 132a may be positioned to be surrounded by the first low-concentration source and drain region 130a, the second high-concentration source and drain region 132b may be positioned to be surrounded by the second low-concentration source and drain region 130b, and the third high-concentration source and drain region 132c may be positioned to be surrounded by the third low-concentration source and drain region 130c.

According to some implementations, as compared to the plurality of low-concentration source and drain regions 130a, 130b, and 130c, the width of each of the plurality of high-concentration source and drain regions 132a, 132b, and 132c in the lateral direction (X direction and/or Y direction) may be less than the width of the plurality of low-concentration source and drain regions 130a, 130b, and 130c in the lateral direction (X direction and/or Y direction). Also, the length of the plurality of high-concentration source and drain regions 132a, 132b, and 132c in the vertical direction (Z direction) may be greater than the length of the plurality of low-concentration source and drain regions 130a, 130b, and 130c in the vertical direction (Z direction). However, this is only an example, and various modifications may be made therein according to some implementations.

The first gate structure 140a may include a first gate dielectric layer 141a, a first lower conductive pattern 142a, a first upper conductive pattern 143a, and a first gate capping pattern 144a that are sequentially stacked on the active region 110 in the vertical direction (Z direction). The second gate structure 140b may include a second gate dielectric layer 141b, a second lower conductive pattern 142b, a second upper conductive pattern 143b, and a second gate capping pattern 144b that are sequentially stacked on the active region 110 in the vertical direction (Z direction).

The first lower conductive pattern 142a, the first upper conductive pattern 143a, the second lower conductive pattern 142b, and the second upper conductive pattern 143b may each include TiN, TiSiN, W, tungsten silicide, or a combination thereof. According to some implementations, the first lower conductive pattern 142a and the second lower conductive pattern 142b may include TiN, TiSiN, or a combination thereof, and the first upper conductive pattern 143a and the second upper conductive pattern 143b may include W.

The first upper conductive pattern 143a may be covered by the first gate capping pattern 144a, and the second upper conductive pattern 143b may be covered by the second gate capping pattern 144b. The first gate capping pattern 144a and the second gate capping pattern 144b may each include a silicon nitride film, a silicon carbonitride film, or a combination thereof.

Both sidewalls of the first gate structure 140a may be covered by a first insulation spacer PGSa. Also, both sidewalls of the second gate structure 140b may be covered by a second insulation spacer PGSb. The first insulation spacer PGSa and the second insulation spacer PGSb may each include an oxide film, a nitride film, or a combination thereof.

The integrated circuit device 100 may include a protective film 151 covering the plurality of low-concentration source and drain regions 130a, 130b, and 130c, the plurality of high-concentration source and drain regions 132a, 132b, and 132c, the active region 110, the first insulation spacer PGSa, and the second insulation spacer PGSb. Portions of the protective film 151 covering the plurality of low-concentration source and drain regions 130a, 130b, and 130c, the plurality of high-concentration source and drain regions 132a, 132b, and 132c, and the active region 110 each extend while maintaining a flat bottom surface. However, since the first insulation spacer PGSa and the second insulation spacer PGSb respectively cover the first gate structure 140a and the second gate structure 140b extending in the vertical direction (Z direction), portions of the protective film 151 covering the first insulation spacer PGSa and the second insulation spacer PGSb may also have arch-like shapes along sidewalls of the first insulation spacer PGSa and the second insulation spacer PGSb, respectively. The protective film 151 may include a silicon nitride film. The first insulation spacer PGSa and the second insulation spacer PGSb may each include an oxide film, a nitride film, or a combination thereof.

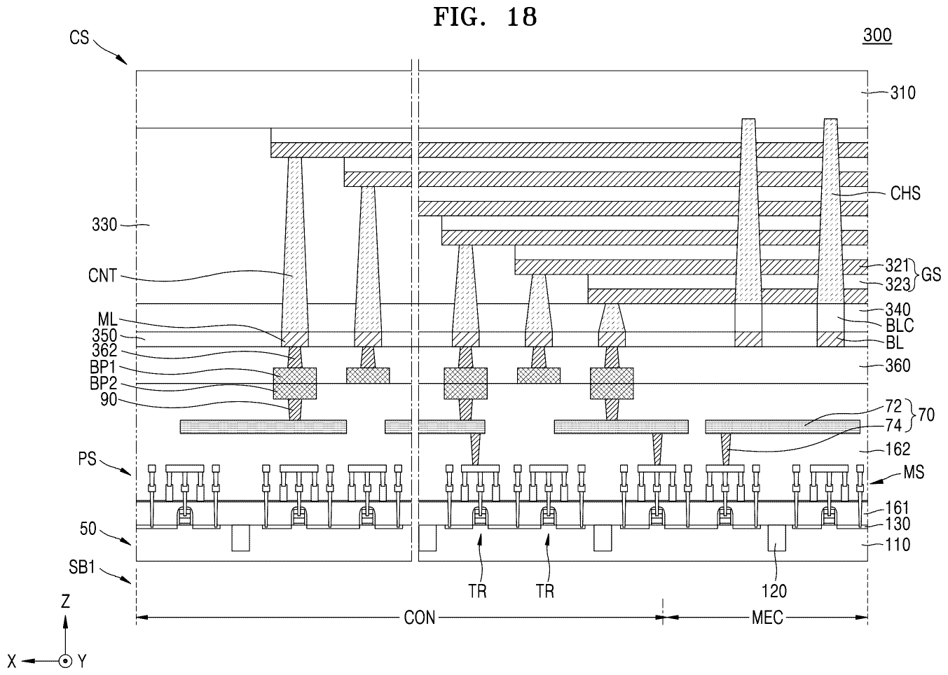

According to some implementations, the integrated circuit device 100 may include the substrate SB, peripheral circuit structures PS (refer to FIG. 18) formed on the substrate SB, and the multilayer wiring structure MMS for connecting the peripheral circuit structures PS (refer to FIG. 18) to each other or connecting the peripheral circuit structures PS (refer to FIG. 18) to components in a cell array structure CS.

The integrated circuit device 100 shown in FIG. 5 may be a component of a peripheral circuit structure PS (refer to FIG. 18) of an integrated circuit device 300 shown in FIG. 18, which will be described later. The multilayer wiring structure MMS included in the peripheral circuit structure PS (refer to FIG. 18) may include a plurality of contacts 170 and a plurality of wiring layers 180. At least some of the plurality of wiring layers 180 may be configured to be electrically connectable to the pass transistor structure TRa. The plurality of contacts 170 may be configured to connect the pass transistor structure TRa and some selected from among the plurality of wiring layers 180 to each other.

The plurality of contacts 170 and the plurality of wiring layers 180 may each include a metal, a conductive metal nitride, a metal silicide, or a combination thereof. For example, the plurality of contacts 170 and the plurality of wiring layers 180 may each include a conductive material such as tungsten, molybdenum, titanium, cobalt, tantalum, nickel, tungsten silicide, titanium silicide, cobalt silicide, tantalum silicide, nickel silicide, etc.

The integrated circuit device 100 may further include a first interlayer insulation layer 161, an etch stop film 152, and a second interlayer insulation layer 162. The etch stop film 152 may be positioned on the substrate SB to extend in the first horizontal direction (X direction). The etch stop film 152 may be disposed to be spaced apart from the protective film 151 in the vertical direction (Z direction). The first interlayer insulation layer 161 may be provided between the protective film 151 and the etch stop film 152, and the second interlayer insulation layer 162 may be provided to be spaced apart from the first interlayer insulation layer 161 with the etch stop film 152 therebetween. In other words, the etch stop film 152 may block the first interlayer insulation layer 161 and the second interlayer insulation layer 162 in the vertical direction (Z direction). According to some implementations, the protective film 151 and the etch stop film 152 may ach include a silicon nitride film. Also, the first interlayer insulation layer 161 and the second interlayer insulation layer 162 may each include Tonen SilaZene (TOSZ).

The multilayer wiring structure MMS may include the plurality of contacts 170 and the plurality of wiring layers 180. The plurality of contacts 170 and the plurality of wiring layers 180 may be covered by the first interlayer insulation layer 161 and the second interlayer insulation layer 162. At this time, the plurality of contacts 170 may penetrate through portions of the first interlayer insulation layer 161 and the second interlayer insulation layer 162 and contact the top surfaces of the plurality of wiring layers 180.

The plurality of contacts 170 may include a plurality of source and drain contacts 171a, 171b, and 171c, a plurality of gate contacts 172a and 172b, and a plurality of peripheral circuit contacts 173 and 174. The plurality of high-concentration source and drain regions 132a, 132b, and 132c may each selectively function as a source region or a drain region according to situations. For example, when the first high-concentration source and drain region 132a functions as a source region, the second high-concentration source and drain region 132b functions as a drain region, and the third high-concentration source and drain region 132c functions as a source region. On the contrary, when the first high-concentration source and drain region 132a functions as a drain region, the second high-concentration source and drain region 132b functions as a source region, and the third high-concentration source and drain region 132c functions as a drain region.

The plurality of source and drain contacts 171a, 171b, and 171c may include a first source and drain contact 171a connected to the first high-concentration source and drain region 132a, a second source and drain contact 171b connected to the second high-concentration source and drain region 132b, and a third source and drain contact 171c connected to the third high-concentration source and drain region 132c. The plurality of gate contacts 172a and 172b may include a first gate contact 172a connected to the first gate structure 140a and a second gate contact 172b connected to the second gate structure 140b. The plurality of peripheral circuit contacts 173 and 174 may include a first peripheral circuit contact 173 and a second peripheral circuit contact 174 connected to the upper end of a second wiring layer 182 and the lower end of a fourth wiring layer 184, which will be described later. At this time, a first peripheral circuit contact 173 and the second peripheral circuit contact 174 may be spaced apart from each other in the first horizontal direction (X direction) with the first gate contact 172a or the second gate contact 172b therebetween.

From among the plurality of source and drain contacts 171a, 171b, and 171c, the source and drain contacts 171a, 171b, and 171c connected to high-concentration source and drain regions 132a and 132b functioning as source regions function as source contacts, and, from among the plurality of source and drain contacts 171a, 171b, and 171c, the source and drain contacts 171a, 171b, and 171c connected to the high-concentration source and drain regions 132a and 132b functioning as drain regions function as drain contacts. For example, when the first source and drain contact 171a functions as a source contact, a memory cell block (hereinafter referred to as a first memory cell block) connected to the first source and drain contact 171a is selected. In this case, the first source and drain contact 171a may receive an operating voltage from the second source and drain contact 171b and transmit the operating voltage to a word line of the first memory cell block. For example, when the first source and drain contact 171a functions as a source contact, the second source and drain contact 171b functions as a drain contact, and the third source and drain contact 171c functions as a source contact. On the contrary, when the first source and drain contact 171a functions as a drain contact, the second source and drain contact 171b functions as a source contact, and the third source and drain contact 171c functions as a drain contact.

The source contact may receive an operating voltage from the drain contact and transmit the operating voltage to the word line WL (refer to FIG. 1) of a selected memory cell block, the string select line SSL (refer to FIG. 1), and the ground select line GSL (refer to FIG. 1). The drain contact may receive an operating voltage from a voltage generating circuit included in the peripheral circuit 30 (refer to FIG. 1) and transmit the operating voltage to the word line WL (refer to FIG. 1) of the selected memory cell block, the string select line SSL (refer to FIG. 1), and the ground select line GSL (refer to FIG. 1). For example, the operating voltage may be a program voltage Vpgm.

The plurality of wiring layers 180 may include first to fourth wiring layers 181, 182, 183, and 184. The first to fourth wiring layers 181, 182, 183, and 184 may be buried in the second interlayer insulation layer 162.

The first source and drain contact 171a may be connected to the first high-concentration source and drain region 132a through the etch stop film 152, the first interlayer insulation layer 161, and the protective film 151. The first source and drain contact 171a extends lengthwise in the vertical direction (Z direction) and may have a tapered shape of which the diameter decreases in a direction toward the substrate SB. In the same regard, the second source and drain contact 171b may be connected to the second high-concentration source and drain region 132b through the etch stop film 152, the first interlayer insulation layer 161, and the protective film 151, and the third source and drain contact 171c may be connected to the third high-concentration source and drain region 132c through the etch stop film 152, the first interlayer insulation layer 161, and the protective film 151. Upper ends of the first source and drain contact 171a, the second source and drain contact 171b, and the third source and drain contact 171c may each be connected to a first wiring layer 181. A plurality of first wiring layers 181 are provided and may be arranged to be spaced apart from each other in the lateral direction (X direction and/or Y direction) with a second wiring layer 182 and a third wiring layer 183 therebetween.

The first gate contact 172a may be connected to the first gate structure 140a through the etch stop film 152. Likewise, the second gate contact 172b may be connected to the second gate structure 140b through the etch stop film 152. The first gate contact 172a and the second gate contact 172b extend lengthwise in the vertical direction (Z direction) and may have a tapered shape of which the diameter decreases in a direction toward the substrate SB. However, the length of the first gate contact 172a in the vertical direction (Z direction) and the length of the second gate contact 172b in the vertical direction (Z direction) may be less than the length of the first source and drain contact 171a in the vertical direction (Z direction) and the length of the second source and drain contact 171b in the vertical direction (Z direction), respectively.

A plurality of third wiring layers 183 may be provided. The plurality of third wiring layers 183 may be arranged to overlap the first gate structure 140a and the second gate structure 140b in the vertical direction (Z direction), respectively. The upper end of the first gate contact 172a and the upper end of the second gate contact 172b may be connected to the third wiring layer 183. The third wiring layer 183 may be disposed between a pair of second wiring layers 182 spaced apart from each other in the first horizontal direction (X direction) over the etch stop film 152.

The second wiring layer 182 may be disposed between the first wiring layer 181 and the third wiring layer 183 in the first horizontal direction (X direction), and the bottom surface of the second wiring layer 182 may be connected to the top surface of the etch stop film 152. A plurality of second wiring layers 182 may be provided, and, in a plan view, the plurality of second wiring layers 182 may be arranged to be spaced apart from each other in the first horizontal direction (X direction) with the plurality of gate structures 140a and 140b therebetween. As shown in FIG. 6, the plurality of second wiring layers 182 and the plurality of first wiring layers 181 may be alternately arranged in the first horizontal direction (X direction). In other words, in a plan view, the second wiring layer 182 may be located between the plurality of gate structures 140a and 140b and the plurality of source and drain contacts 171a, 171b, and 171c. The second wiring layer 182 is connected to the etch stop film 152 and does not penetrate through the etch stop film 152. The second wiring layer 182 is positioned to be spaced apart from the protective film 151 in the vertical direction (Z direction) over the substrate SB and does not contact the first interlayer insulation layer 161. As shown in FIG. 5 and FIG. 6, the second wiring layer 182 extends in the second horizontal direction (Y direction) from one side of a pair of gate structures 140a and 140b, and the second wiring layer 182 may vertically overlap portions of the plurality of low-concentration source and drain regions 130a, 130b, and 130c. According to some implementations, the length of the second wiring layer 182 in the second horizontal direction (Y direction) may be greater than the length of the second wiring layer 182 in the first horizontal direction (X direction).

The first peripheral circuit contact 173 may extend in the vertical direction (Z direction) within the second interlayer insulation layer 162 and be connected to the upper end of the second wiring layer 182. The first peripheral circuit contact 173 may have a tapered shape of which the diameter decreases in a direction toward the substrate SB. The second peripheral circuit contact 174 may extend in the vertical direction (Z direction) within the second interlayer insulation layer 162 and be connected to the upper end of the third wiring layer 183. The second peripheral circuit contact 174 may have a tapered shape of which the diameter decreases in a direction toward the substrate SB.

Since the first wiring layer 181, the second wiring layer 182, and the third wiring layer 183 all extend lengthwise in the vertical direction (Z direction), the first wiring layer 181, the second wiring layer 182, and the third wiring layer 183 are similar to first to third second source and drain contacts 171a to 171c and first and second gate contacts 172a and 172b. However, the first wiring layer 181, the second wiring layer 182, and the third wiring layer 183 have a greater width in the lateral direction (X direction and/or Y direction) as compared to the first to third second source and drain contacts 171a to 171c and the first and second gate contacts 172a and 172b, and thus the first wiring layer 181, the second wiring layer 182, and the third wiring layer 183 have a smaller aspect ratio.

According to some implementations, the fourth wiring layer 184 may be disposed on the first peripheral circuit contact 173 and the second peripheral circuit contact 174 within the second interlayer insulation layer 162. The bottom surface of the fourth wiring layer 184 may be connected to the upper end of the first peripheral circuit contact 173 and the upper end of the second peripheral circuit contact 174. The fourth wiring layer 184 may extend in the lateral direction (X direction and/or Y direction) and be positioned to overlap both a pair of first peripheral circuit contacts 173 and the second peripheral circuit contact 174. The length of the fourth wiring layer 184 in the first horizontal direction (X direction) may be greater than the length of the fourth wiring layer 184 in the vertical direction (Z direction) such that both the upper ends of the pair of first peripheral circuit contacts 173 and the upper end of the second peripheral circuit contact 174 are connected to the fourth wiring layer 184. On the contrary, the length of the second wiring layer 182 in the vertical direction (Z direction) may be greater than the length of the second wiring layer 182 in the first horizontal direction (X direction) such that the second wiring layer 182 extends lengthwise in the vertical direction (Z direction) to be physically and electrically connected to the etch stop film 152. In this way, as the fourth wiring layer 184 is physically and electrically connected to the pair of first peripheral circuit contacts 173 and the second peripheral circuit contact 174, the pair of first peripheral circuit contacts 173 and the second peripheral circuit contact 174 may be electrically connected to each other via the fourth wiring layer 184.

A high operating voltage may be applied to the fourth wiring layer 184. Since the fourth wiring layer 184 is electrically connected to the first peripheral circuit contact 173 and the second peripheral circuit contact 174, a high voltage applied to the fourth wiring layer 184 may be applied to the second wiring layer 182 electrically connected to the first peripheral circuit contact 173 and the gate structures 140a and 140b electrically connected to the second peripheral circuit contact 174. The second wiring layer 182 is physically connected to the etch stop film 152 including an insulation material. Therefore, the second wiring layer 182 to which a high voltage is applied may generate a field effect at the plurality of low-concentration source and drain regions 130a, 130b, and 130c and the plurality of high-concentration source and drain regions 132a, 132b, and 132c through the etch stop film 152 and the first interlayer insulation layer 161 disposed below the etch stop film 152. Through the field effect, the resistances of the plurality of low-concentration source and drain regions 130a, 130b, and 130c and the plurality of high-concentration source and drain regions 132a, 132b, and 132c are reduced, and the reduction of the resistances enhances the flow of currents through the plurality of low-concentration source and drain regions 130a, 130b, and 130c and the plurality of high-concentration source and drain regions 132a, 132b, and 132c. For example, since the second wiring layer 182 is electrically connected to the first gate contact 172a and a high voltage is applied to the second wiring layer 182 and the first gate contact 172a at the same time, the flow of a current desired through the first gate structure 140a is improved in conjunction with the operation of the first gate structure 140a.

On the contrary, in the case of improving the flow of a current between the first low-concentration source and drain region 130a and the second low-concentration source and drain region 130b through the first gate structure 140a, no voltage is applied to the second gate structure 140b, and thus the flow of a current between the second low-concentration source and drain region 130b and the third low-concentration source and drain region 130c is weakened. At this time, while no voltage is applied to the second wiring layer 182 disposed over the second low-concentration source and drain region 130b and the third low-concentration source and drain region 130c, the resistances of the second low-concentration source and drain region 130b and the third low-concentration source and drain region 130c increase due to the field effect. When the resistances of the second low-concentration source and drain region 130b and the third low-concentration source and drain region 130c increase, the phenomenon in which a voltage applied to the second gate structure 140b exceeds a breakdown voltage and the leakage current rapidly increases may be prevented.

According to some implementations, the bottom surface of the first wiring layer 181 and the bottom surface of the third wiring layer 183 are on the same plane and are at the same vertical level LV1 in the vertical direction (Z direction). As described in detail below, the first wiring layer 181 and the third wiring layer 183 are fabricated by forming holes in the second interlayer insulation layer 162 and then filling the holes with a conductive material. At this time, a hole for forming the first wiring layer 181 and a hole for forming the third wiring layer 183 are formed to have the same depth, and thus the bottom surface of the first wiring layer 181 and the bottom surface of the third wiring layer 183 are at the same vertical level LV1. However, according to some implementations, the bottom surface of the first wiring layer 181 and the bottom surface of the third wiring layer 183 may be at different vertical levels.

According to some implementations, a length L2 of the second wiring layer 182 in the vertical direction (Z direction) is greater than a length L1 of the first wiring layer 181 in the vertical direction (Z direction). As described in detail below, the first wiring layer 181 and the second wiring layer 182 are fabricated by forming holes in the second interlayer insulation layer 162 and then filling the holes with a conductive material. Afterwards, the conductive material filling the holes is ground through a chemical mechanical polishing (CMP) process, and thus the top surface of the first wiring layer 181 and the top surface of the second wiring layer 182 are on the same plane and are at the same vertical level LV2. In the same way, the top surface of the second wiring layer 182 and the top surface of the third wiring layer 183 are also on the same plane and are at the same vertical level LV3. On the other hand, the bottom surface of the second wiring layer 182 may be disposed at a lower vertical level than the bottom surface of the first wiring layer 181. Unlike the first wiring layer 181 or the third wiring layer 183, the second wiring layer 182 is in contact with the etch stop film 152 and needs to generate a field effect at the plurality of low-concentration source and drain regions 130a, 130b, and 130c and the plurality of high-concentration source and drain regions 132a, 132b, and 132c through a high voltage applied to the second wiring layer 182, and thus the length of the second wiring layer 182 in the vertical direction (Z direction) is greater than the length of the first wiring layer 181 or the third wiring layer 183 in the vertical direction (Z direction).

According to some implementations, a topmost surface 151_ut of the protective film 151 is located further away from the substrate SB in the vertical direction (Z direction) than a top surface 152_u of the etch stop film 152. In other words, a distance L3 from the top surface of the substrate SB to the topmost surface 151_ut of the protective film 151 is smaller than a distance L4 from the top surface of the substrate SB to the top surface 152_u of the etch stop film 152. Therefore, when viewed in a cross-section perpendicular to the first horizontal direction (X direction) and the vertical direction (Z direction), the topmost surface 151_ut of the protective film 151 is located apart from the top surface of the etch stop film 152 in the vertical direction (Z direction), and the bottom surface of the second wiring layer 182 is also located apart from the topmost surface 151_ut of the protective film 151 in the vertical direction (Z direction). As the etch stop film 152 is located further away from the substrate SB in the vertical direction (Z direction) than the protective film 151, the etch stop film 152 may be easily formed to have a conformal thickness on the first interlayer insulation layer 161 regardless the locations of the plurality of gate structures 140a and 140b or the location of the protective film 151.

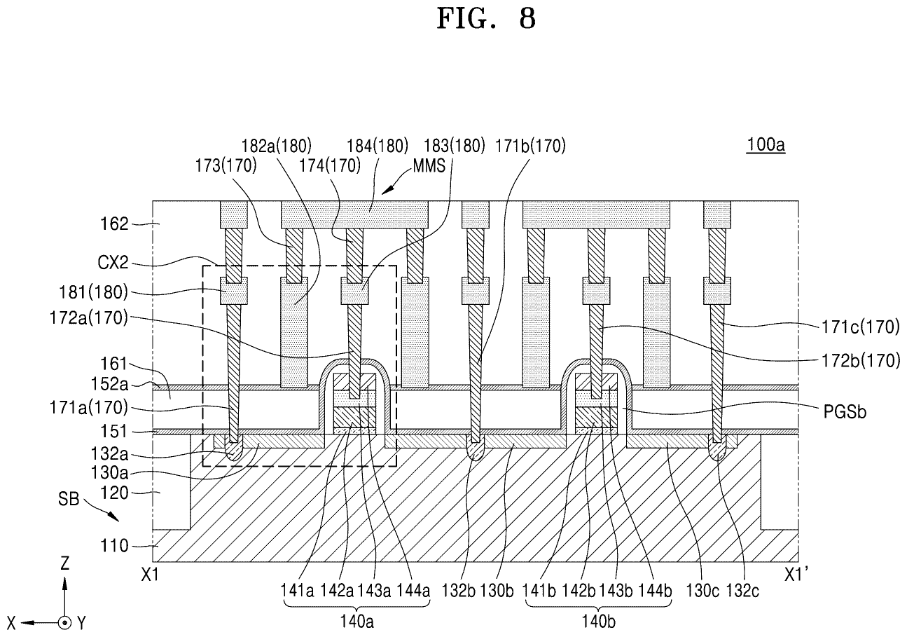

FIG. 8 is a cross-sectional view of an example of an integrated circuit device 100a, which corresponds to the cross-sectional view of FIG. 6, and FIG. 9 is an example enlarged view of a region “CX2” of FIG. 8.

The integrated circuit device 100a shown in FIGS. 8 and 9 is almost identical or similar to the integrated circuit device 100 shown in FIGS. 5 to 7 except that the location of the etch stop film 152 is different from that shown in FIGS. 5 to 7 and the length of the second wiring layer 182 in the vertical direction (Z direction) is greater than that shown in FIGS. 5 to 7 due to the change in the location of the etch stop film 152. Therefore, descriptions of the components already given above with reference to FIGS. 5 to 7 will be omitted or briefly given below.

According to some implementations, a topmost surface 151_ut of the protective film 151 is located closer to the substrate SB in the vertical direction (Z direction) than a top surface 152_u of the etch stop film 152. In other words, a distance L3_a from the top surface of the substrate SB to the topmost surface 151_ut of the protective film 151 is greater than a distance L4_a from the top surface of the substrate SB to the top surface 152_u of the etch stop film 152. Therefore, when viewed in a cross-section perpendicular to the first horizontal direction (X direction) and the vertical direction (Z direction), the bottom surface of the second wiring layer 182 is located closer to the substrate SB than the topmost surface 151_ut of the protective film 151. As the etch stop film 152 is located closer to the substrate SB in the vertical direction (Z direction) than the protective film 151, the second wiring layer 182 to which a high voltage is applied may generate a stronger field effect at the plurality of low-concentration source and drain regions 130a, 130b, and 130c and the plurality of high-concentration source and drain regions 132a, 132b, and 132c through the etch stop film 152 and the first interlayer insulation layer 161. Therefore, through the stronger field effect, the resistances of the plurality of low-concentration source and drain regions 130a, 130b, and 130c and the plurality of high-concentration source and drain regions 132a, 132b, and 132c are further reduced, and the reduction of the resistances further enhances the flow of currents through the plurality of low-concentration source and drain regions 130a, 130b, and 130c and the plurality of high-concentration source and drain regions 132a, 132b, and 132c.

On the contrary, while no voltage is applied to the second wiring layer 182 disposed over the second low-concentration source and drain region 130b and the third low-concentration source and drain region 130c, the resistances of the second low-concentration source and drain region 130b and the third low-concentration source and drain region 130c further increase due to the stronger field effect. When the resistances of the second low-concentration source and drain region 130b and the third low-concentration source and drain region 130c further increase, the phenomenon in which a voltage applied to the second gate structure 140b exceeds a breakdown voltage and the leakage current rapidly increases may be prevented more effectively.

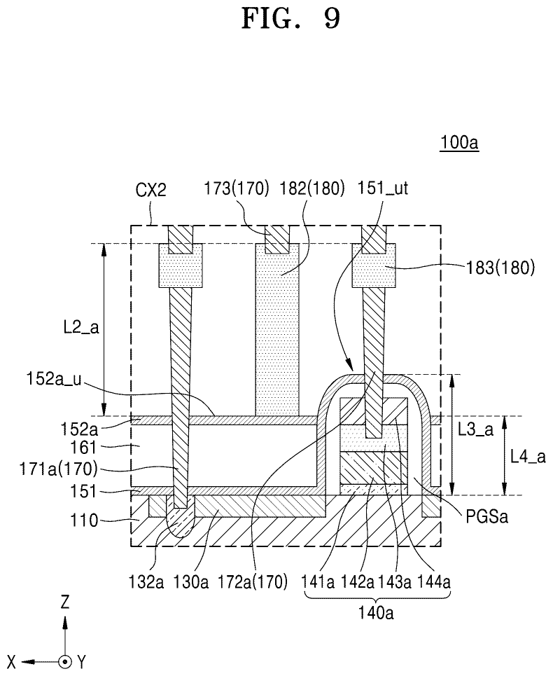

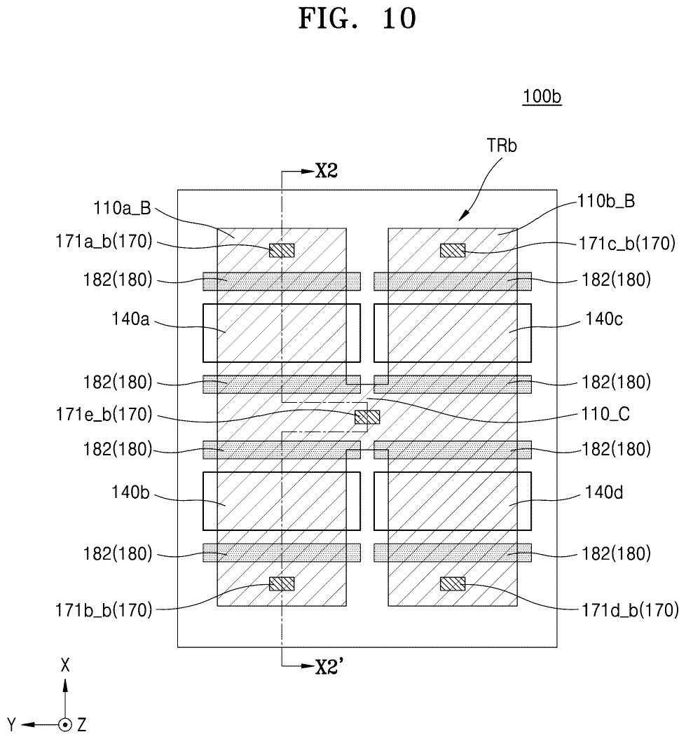

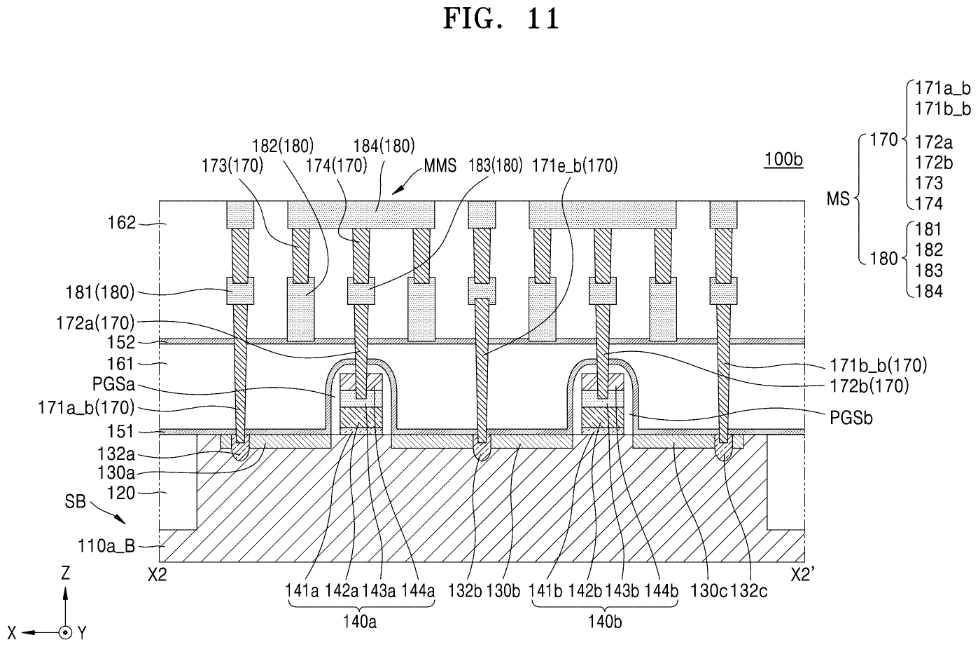

FIG. 10 is a layout diagram showing an example of an integrated circuit device 100b, and FIG. 11 is an example cross-sectional view taken along a line X2-X2′ of FIG. 10. In an integrated circuit device 100b shown in FIGS. 10 and 11, the shape of a pass transistor structure TRb (in detail, the layout of the active region 110) is different from that in the integrated circuit device 100 shown in FIGS. 5 to 7. Hereinafter, descriptions below will focus on the differences from the integrated circuit device 100 shown in FIGS. 5 to 7.

According to some implementations, the substrate SB may include the device isolation layer 120 and the active region 110 defined by the device isolation layer 120. At this time, the active region 110 may include a pair of base active regions 110 extending in the first horizontal direction (X direction) and spaced apart from each other in the second horizontal direction (Y direction). The pair of base active regions 110 may include a first base active region 110a_B and a second base active region 110b_B spaced apart from the first base active region 110a_B in the second horizontal direction (Y direction). Also, the active region 110 may include a center active region 110_C integrated with the pair of base active regions 110 and extending in the second horizontal direction (Y direction) between the pair of base active regions 110. The center active region 110_C may have a rectangular shape in a plan view. The first base active region 110a_B and the second base active region 110b_B may each have a rectangular shape with the length in the first horizontal direction (X direction) greater than the length in the second horizontal direction (Y direction). The width of the center active region 110_C in the first horizontal direction (X direction) may be less than the width of the first base active region 110a_B in the first horizontal direction (X direction) and the width of the second base active region 110b_B in the horizontal direction (X direction).

The integrated circuit device 100b may include first to fourth gate structures 140a, 140b, 140c, and 140d, the plurality of second wiring layers 182 extending lengthwise in the second horizontal direction (Y direction), and first to fifth source and drain contacts 171a_b, 171b_b, 171c_b, 171d_b, and 171e_b.

The first gate structure 140a and the second gate structure 140b arranged to be spaced apart from each other in the first horizontal direction (X direction) may be located on the first base active region 110a_B. Also, a third gate structure 140c and a fourth gate structure 140d arranged to be spaced apart from each other in the first horizontal direction (X direction) may be located on the second base active region 110b_B. The plurality of second wiring layers 182 may be positioned to be spaced apart from each other in the first horizontal direction (X direction) with a plurality of gate structures 140a and 140b, 140c, and 140d therebetween.

In a plan view, a first source and drain contact 171a_b and a second source and drain contact 171b_b may be located at positions outside the first base active region 110a_B along a line in the first horizontal direction (X direction). A third source and drain contact 171c_b and a fourth source and drain contact 171d_b may be located at positions outside the second base active region 110b_B along a line in the first horizontal direction (X direction). Also, a fifth source and drain contact 171e_b may be located in the center active region 110_C. In other words, a high-concentration source and drain region to be connected to the fifth source and drain contact 171e_b may be located in the center active region 110_C.

According to some implementations, the fifth source and drain contact 171e_b may be disposed in a diagonal direction from the first to fourth gate structures 140a, 140b, 140c, and 140d in a plan view. According to some implementations, respective separation distances from the fifth source and drain contact 171e_b to the first to fourth gate structures 140a and 140b, 140c, and 140d may be identical to one another. As the fifth source and drain contact 171e_b is disposed in a diagonal direction from the first to fourth gate structures 140a, 140b, 140c, and 140d, the area of the active region 110 may be reduced while the separation distances between the fifth source and drain contact 171e_b and the first to fourth gate structures 140a, 140b, 140c, and 140d are maintained. Therefore, break-down of the first to fourth gate structures 140a, 140b, 140c, and 140d that may occur when the separation distances between the fifth source and drain contact 171e_b and the first to fourth gate structures 140a, 140b, 140c, and 140d are reduced may be prevented.

According to some implementations, the first base active region 110a_B and the second base active region 110b_B may be line-symmetrical with respect to each other around an imaginary straight line that extends through the center of the center active region 110_C in the first horizontal direction (X direction).

In the case of the integrated circuit device 100 shown in FIG. 5, the distance from the first gate structure 140a to the first source and drain contact 171a is identical to the distance from the first gate structure 140a to the second source and drain contact 171b. Also, the distance from the second gate structure 140b to the second source and drain contact 171b is identical to the distance from the second gate structure 140b to the third source and drain contact 171c. However, in the case of the integrated circuit device 100b shown in FIG. 10, the distance from the first gate structure 140a to the first source and drain contact 171a_b is different from the distance from the first gate structure 140a to the fifth source and drain contact 171e_b. Also, the distance from the second gate structure 140b to the second source and drain contact 171b_b is different from the distance from the second gate structure 140b to the fifth source and drain contact 171e_b. Also, the distance from the third gate structure 140c to the third source and drain contact 171c_b is different from the distance from the third gate structure 140c to the fifth source and drain contact 171e_b. Also, the distance from the fourth gate structure 140d to the fourth source and drain contact 171d_b is different from the distance from the fourth gate structure 140d to the fifth source and drain contact 171e_b.

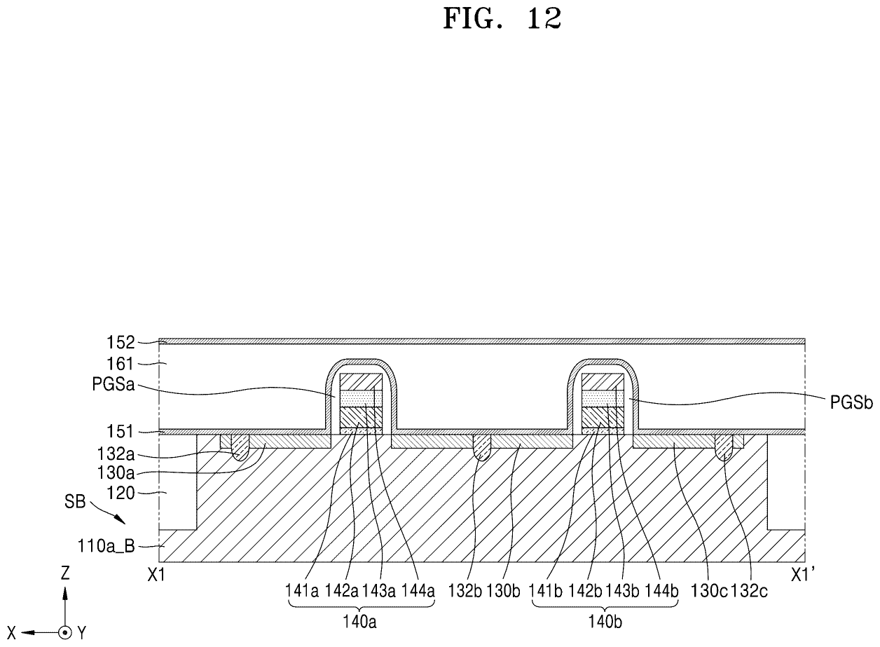

FIGS. 12 to 17 are example cross-sectional views sequentially showing some of operations of the process of manufacturing the integrated circuit device 100 shown in FIGS. 5 to 7.

Referring to FIG. 12, first, the pair of gate structures 140a and 140b may be formed on the substrate SB, and the etch stop film 152 may be formed on the gate structures 140a and 140b. At this time, the substrate SB may include the device isolation layer 120, the active region 110 located within the device isolation layer 120, the plurality of low-concentration source and drain regions 130a, 130b, and 130c located within the active region 110 and spaced apart from one another in the first horizontal direction (X direction), and the plurality of high-concentration source and drain regions 132a, 132b, and 132c located inside the plurality of low-concentration source and drain regions 130a, 130b, and 130c and more densely doped than the plurality of low-concentration source and drain regions 130a, 130b, and 130c.

The pair of gate structures 140a and 140b may include the first gate structure 140a and the second gate structure 140b that are spaced apart from each other in the first horizontal direction (X direction), and the pair of gate structures 140a and 140b may include gate dielectric layers 141a and 141b, lower conductive patterns 142a and 142b, upper conductive patterns 143a and 143b, and gate capping patterns 144a and 144b that are stacked in the vertical direction (Z direction). Also, the top surfaces and the side surfaces of the pair of gate structures 140a and 140b may be surrounded by insulation spacers PGSa and PGSb, respectively.

The etch stop film 152 may extend in the first horizontal direction (X direction) over the substrate SB, and the top surface of the etch stop film 152 may be higher than the top surfaces of the gate structures 140a and 140b.

According to some implementations, the protective film 151 covering the low-concentration source and drain regions 130a, 130b, and 130c and the gate structures 140a and 140b may be positioned on the substrate SB. According to some implementations, the protective film 151 and the etch stop film 152 may include silicon nitride, silicon oxynitride, a high-k material, or a combination thereof.

The first interlayer insulation layer 161 may be provided between the protective film 151 and the etch stop film 152. The first interlayer insulation layer 161 may include Tonen SilaZene (TOSZ), but is not limited thereto. The bottom surface of the first interlayer insulation layer 161 may extend along the protective film 151, and the top surface of the first interlayer insulation layer 161 may extend along the bottom surface of the etch stop film 152.

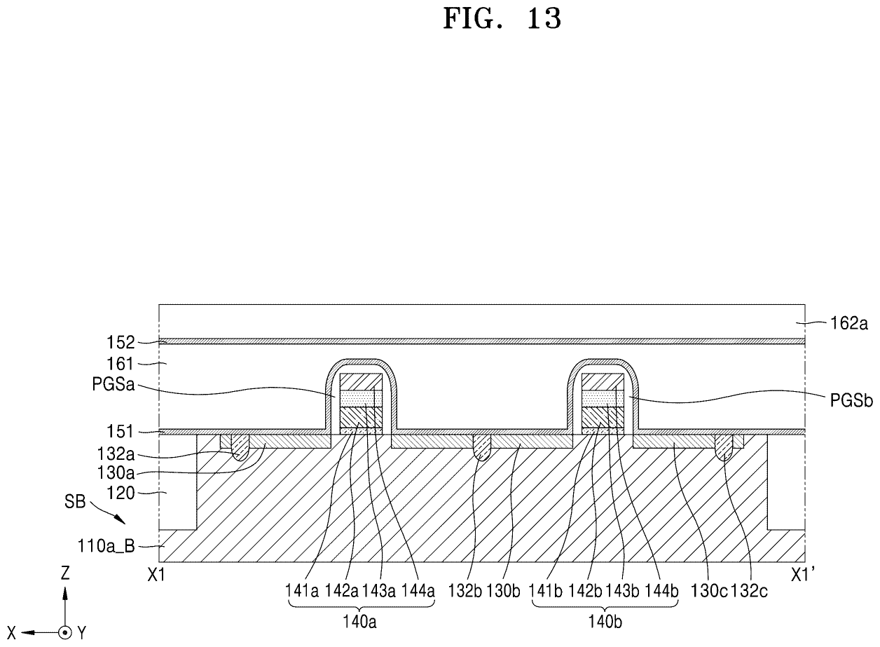

Referring to FIG. 13, an interlayer insulation material 162a may be formed on the top surface of the etch stop film 152. Here, the interlayer insulation material 162a may include the same material as the first interlayer insulation layer 161.

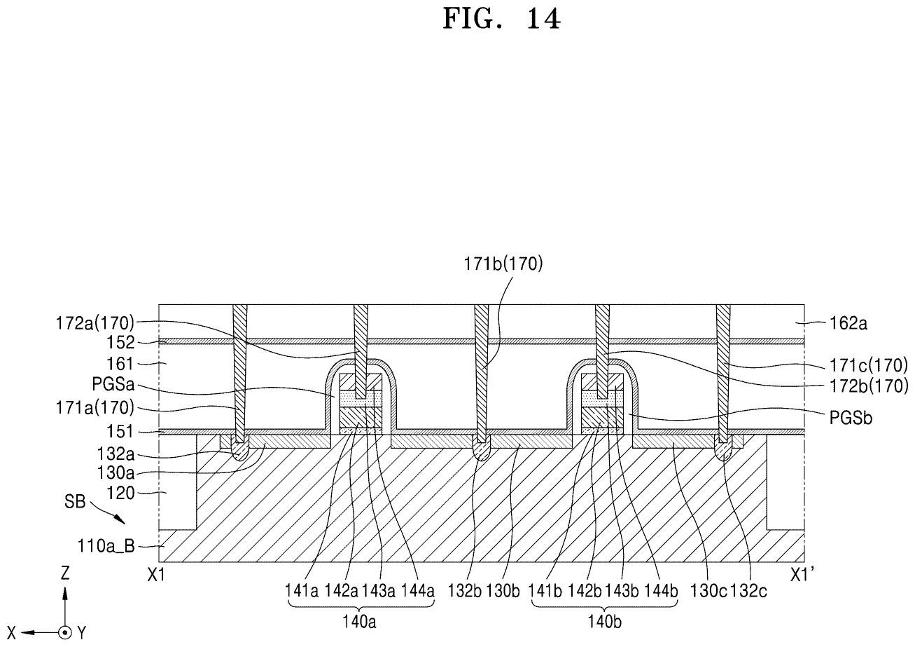

Referring to FIG. 14, the plurality of source and drain contacts 171a, 171b, and 171c and the plurality of gate contacts 172a and 172b may be formed. The plurality of source and drain contacts 171a, 171b, and 171c are formed by forming holes penetrating through the interlayer insulation material 162a, the etch stop film 152, and the protective film 151 and then filling the holes with a conductive material. The plurality of source and drain contacts 171a, 171b, and 171c may be connected to the high-concentration source and drain regions 132a, 132b, and 132c. Here, the plurality of source and drain contacts 171a, 171b, and 171c may each have a tapered shape of which the diameter decreases in a direction toward the substrate SB. The plurality of source and drain contacts 171a, 171b, and 171c may include the first source and drain contact 171a connected to the first high-concentration source and drain region 132a, the second source and drain contact 171b connected to the second high-concentration source and drain region 132b, and the third source and drain contact 171c connected to the third high-concentration source and drain region 132c.

The plurality of gate contacts 172a and 172b may be formed by filling holes, which penetrate through the interlayer insulation material 162a, the etch stop film 152, and the protective film 151 and are formed by etching portions of the plurality of gate structures 140a and 140b, with a conductive material. The plurality of gate contacts 172a and 172b may be connected to the plurality of gate structures 140a and 140b, respectively. The plurality of gate contacts 172a and 172b may each have a tapered shape of which the diameter decreases in a direction toward the substrate SB. The plurality of gate contacts 172a and 172b may include the first gate contact 172a connected to the first gate structure 140a and the second gate contact 172b connected to the second gate structure 140b.

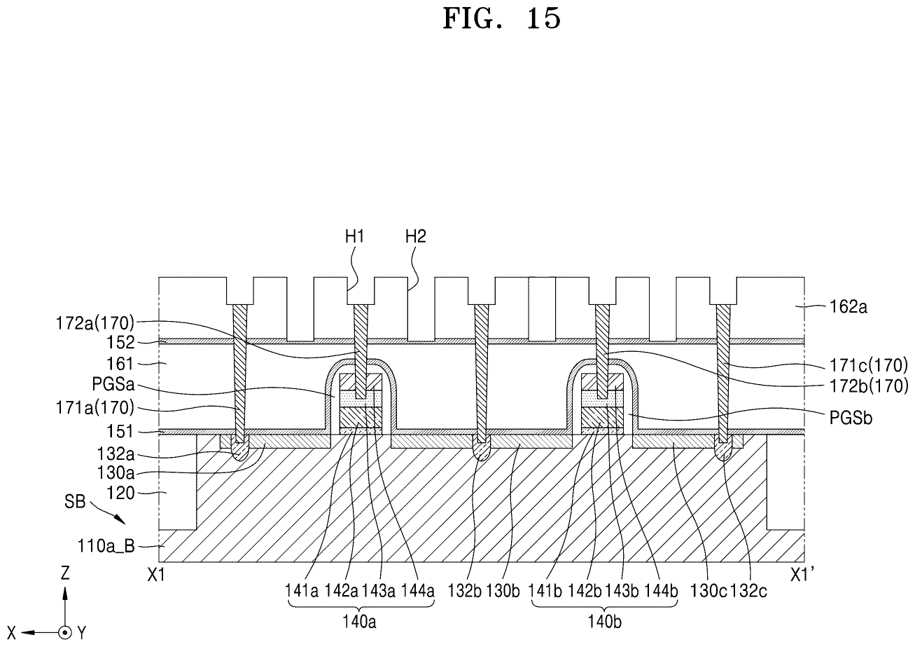

Referring to FIG. 15, a first hole H1 and a second hole H2 may be formed by etching the interlayer insulation material 162a. The first hole H1 may be formed to vertically overlap the plurality of source and drain contacts 171a, 171b, and 171c and the plurality of gate contacts 172a and 172b, and the second hole H2 may be formed in a space between one of a plurality of source and drain contacts and one of the plurality of gate contacts 172a and 172b. A plurality of first holes H1 and a plurality of second holes H2 are provided, and the plurality of first holes H1 and the plurality of second holes H2 may be located side-by-side and spaced apart from each other in the first horizontal direction (X direction).

The plurality of first holes H1 may be formed by using the plurality of source and drain contacts 171a, 171b, and 171c and the plurality of gate contacts 172a and 172b as an etch stop material. In other words, in the process of forming the plurality of first holes H1, the interlayer insulation material 162a may be etched so that the plurality of source and drain contacts 171a, 171b, and 171c and the plurality of gate contacts 172a and 172b are exposed.

The plurality of second holes H2 may be formed by using the etch stop film 152 as an etch stop material. In other words, in the process of forming the plurality of second holes H2, the interlayer insulation material 162a may be etched so that a plurality of etch stop films 152 are exposed.

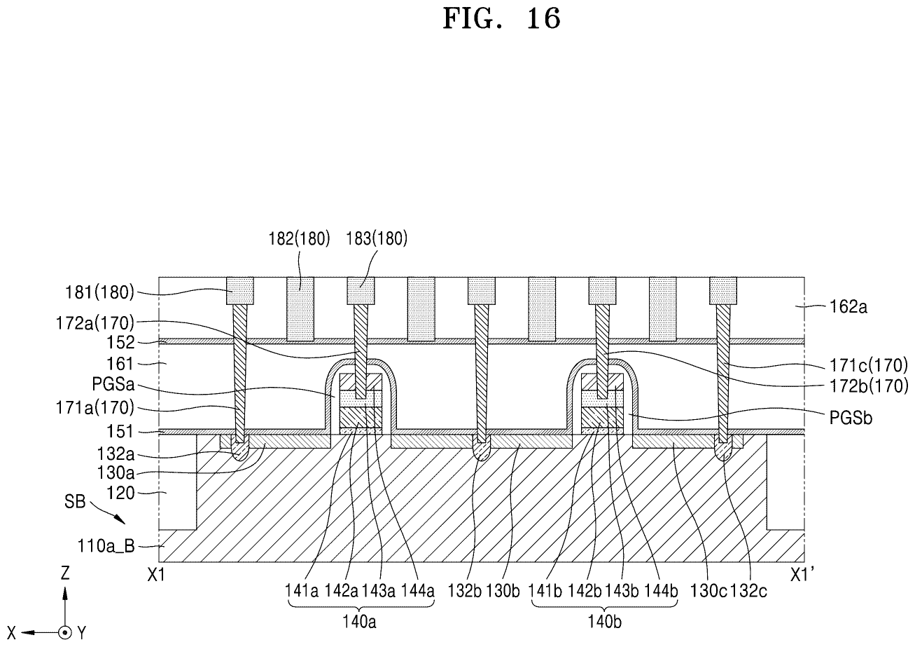

Referring to FIG. 16, the first wiring layer 181 and the third wiring layer 183 may be formed by filling the first hole H1 with a conductive material. Also, the second wiring layer 182 may be formed by filling the second hole H2 with a conductive material. Since the depth of the second hole H2 in the vertical direction (Z direction) is greater than the depth of the first hole H1 in the vertical direction (Z direction), the length of the second wiring layer 182 in the vertical direction (Z direction) may also be greater than the lengths of the first wiring layer 181 and the third wiring layer 183 in the vertical direction (Z direction).

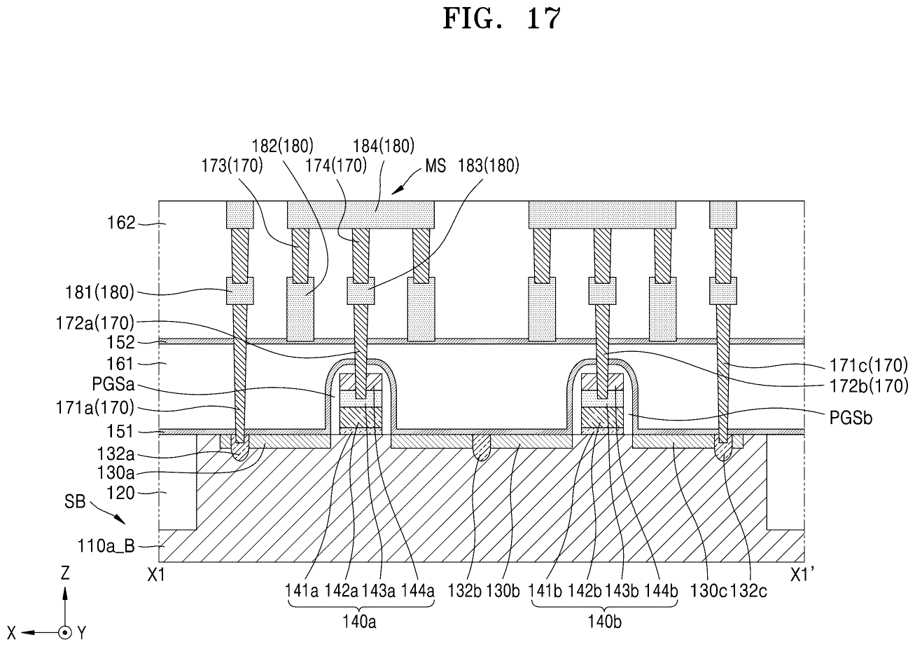

Referring to FIG. 17, an insulation material may be stacked on the interlayer insulation material 162a. Thereafter, through a process similar to the process of fabricating the plurality of source and drain contacts 171a, 171b, and 171c and the plurality of gate contacts 172a and 172b, the first peripheral circuit contact 173 and the second peripheral circuit contact 174 may be fabricated. Also, the fourth wiring layer 184 may be formed through a process similar to the process of fabricating the first wiring layer 181, the second wiring layer 182, and the third wiring layer 183.

Both the upper end of the first peripheral circuit contact 173 and the upper end of the second peripheral circuit contact 174 may be connected to the fourth wiring layer 184. At this time, the second wiring layer 182 may be electrically connected to the plurality of gate contacts 172a and 172b through the first peripheral circuit contact 173, the fourth wiring layer 184, the second peripheral circuit contact 174, and the third wiring layer 183.

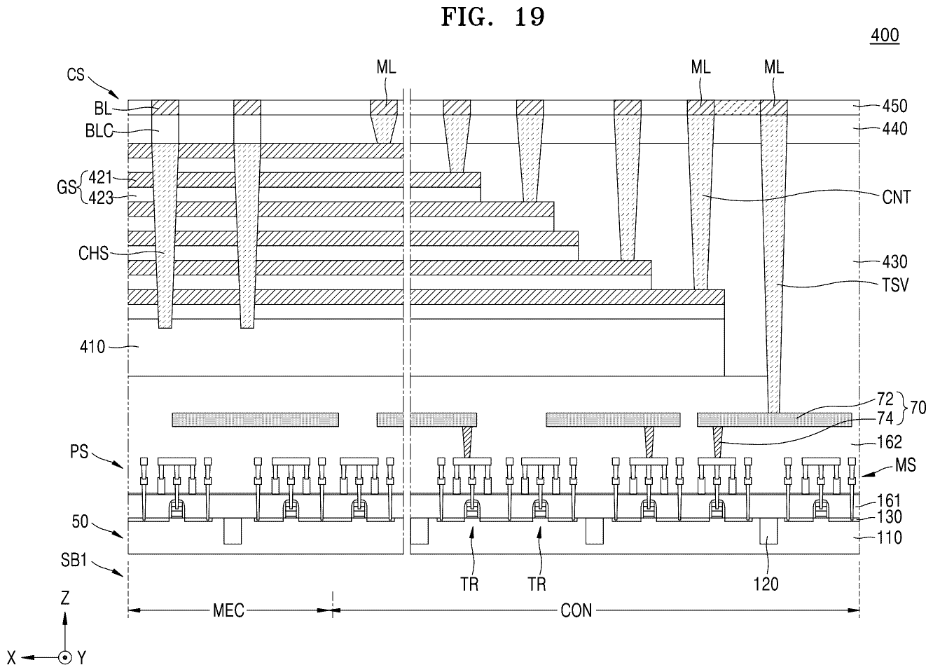

FIGS. 18 and 19 are example diagrams each schematically showing an electronic system including an integrated circuit element.

Referring to FIG. 18, the integrated circuit device 300 may include the cell array structure CS and the peripheral circuit structure PS that overlap each other in the vertical direction (Z direction). According to some implementations, the cell array structure CS may be disposed at a higher vertical level than the peripheral circuit structure PS. The cell array structure CS may include a memory cell region MEC and a connection region CON disposed on one side of the memory cell region MEC in the first horizontal direction (X direction).

According to some implementations, the integrated circuit device 300 may have a chip-to-chip (C2C) structure. The C2C structure may be obtained by forming the cell array structure CS on a first wafer, forming the peripheral circuit structure PS on a second wafer that is different from the first wafer, and then connecting the cell array structure CS and the peripheral circuit structure PS to each other by using a bonding method. For example, the above-stated bonding method may refer to a method of bonding a first bonding pad BP1 of the cell array structure CS and a second bonding pad BP2 of the peripheral circuit structure PS, such that the first bonding pad BP1 and the second bonding pad BP2 may be electrically connected to each other. According to some implementations, when the first bonding pad BP1 and the second bonding pad BP2 include copper (Cu), the bonding method may be a Cu-Cu bonding method. According to some implementations, the first bonding pad BP1 and the second bonding pad BP2 may each include aluminum (Al) or tungsten (W).

The peripheral circuit structure PS may include a substrate 50, a pass transistor TR disposed on the substrate 50, and the multilayer wiring structure MMS.

A first substrate SB1 may include a semiconductor substrate. For example, the first substrate SB1 may include Si, Ge, or SiGe. The active region 110 may be defined on the substrate SB1 by the device isolation layer 120, and a plurality of pass transistors TR may be formed on the active region 110. The first substrate SB1 may have the same configuration as the substrate SB shown in FIG. 5. The plurality of pass transistors TR may include the plurality of gate structures 140a and 140b (refer to FIG. 6) and the plurality of low-concentration source and drain regions 130a, 130b, and 130c arranged on portions of the substrate SB on both sides of the plurality of gate structures 140a and 140b (refer to FIG. 6). According to some implementations, the plurality of pass transistors TR may include at least one of the structures described above with reference to FIGS. 5 to 11 for pass transistors TRa and TRb included in integrated circuit devices 100, 100a, and 100b.

The integrated circuit device 300 according to some implementations may include a plurality of peripheral circuit wiring structures 70. The plurality of peripheral circuit wiring structures 70 may include a plurality of peripheral circuit wiring layers 72 and a plurality of peripheral circuit contacts 74. At least some of the plurality of peripheral circuit wiring layers 72 may be configured to be electrically connectable to the pass transistor TR. The plurality of peripheral circuit contacts 74 may be configured to connect some selected from among the plurality of pass transistors TR and some selected from among the plurality of peripheral circuit wiring layers 72 to each other. The plurality of pass transistors TR and the plurality of peripheral circuit wiring structures 70 included in the peripheral circuit structure PS may be covered by the second interlayer insulation layer 162. The second interlayer insulation layer 162 has the same configuration as that of the second interlayer insulation layer 162 shown in FIG. 5.

A plurality of second bonding pads BP2 may be arranged on the second interlayer insulation layer 162. The plurality of second bonding pads BP2 may be connected to the plurality of peripheral circuit wiring structures 70 through second bonding vias 90, respectively. According to some implementations, the top surface of the second bonding pad BP2 may be coplanar with the top surface of the second interlayer insulation layer 162. The second bonding pad BP2 may include a conductive material including copper (Cu), gold (Au), silver (Ag), aluminum (Al), tungsten (W), titanium (Ti), tantalum (Ta), or a combination thereof.

The cell array structure CS may include a cell stack structure GS disposed on a second substrate SB2. The cell stack structure GS may include a plurality of gate electrodes 321 and a plurality of insulation layers 323 that are alternately arranged in the vertical direction. The plurality of gate electrodes 321 may include, for example, tungsten, nickel, cobalt, tantalum, tungsten nitride, titanium nitride, tantalum nitride, or a combination thereof. The plurality of insulation layers 323 may include silicon oxide, silicon nitride, or silicon oxynitride.

Referring to FIG. 4, the plurality of gate electrodes 321 may correspond to the ground select line GSL, the word line WL, and at least one string select line SSL that constitute a memory cell string MS. For example, one uppermost gate electrode 321 may function as the ground select line GSL, two lowermost gate electrodes 321 may function as the string select lines SSL, and the remaining gate electrodes 321 may function as the word lines WL. Therefore, the memory cell string MS in which the ground select transistor GST, the string select transistor SST, and memory cell transistors MC1, MC2, . . . , MCn-1, and MCn are connected in series therebetween may be provided.

The cell stack structure GS may extend to have a smaller length in the first horizontal direction (X direction) on the connection region CON as it moves away from the second substrate SB2. In other words, the cell stack structure GS may have a step-like shape. For example, the cell stack structure GS may extend to have a greater length in the first horizontal direction (X direction) on the connection region CON as it moves away from the peripheral circuit structure PS.

The second substrate SB2 and the cell stack structure GS may be covered by a cover insulation layer 330. The cover insulation layer 330 may include a silicon oxide film, a silicon nitride film, or a combination thereof.

A plurality of channel structures CHS may penetrate through the cell stack structure GS and extend in the vertical direction on the memory cell region MEC. The plurality of channel structures CHS may be arranged to be spaced apart from one another by a certain distance. The plurality of channel structures CHS may be arranged in a zigzag shape or a staggered shape. According to some implementations, the plurality of channel structures CHS may be arranged to extend into the second substrate SB2. According to some implementations, the plurality of channel structures CHS may be arranged to contact the bottom surface of the second substrate SB2.

The plurality of channel structures CHS may be arranged in channel holes penetrating through the cell stack structure GS, respectively. The plurality of channel structures CHS may each include a gate insulation layer, a channel layer, a buried insulation layer, and a conductive plug. The gate insulation layer and the channel layer may be sequentially arranged on the sidewall of a channel hole. The buried insulation layer filling the remaining space of the channel hole may be disposed on the channel layer. The conductive plug may be disposed in contact with the channel layer to block the entrance of the channel hole.

The bottom surfaces of the plurality of channel structures CHS may contact a plurality of bit line contacts BLC, respectively. The plurality of bit line contacts BLC may penetrate through a first insulation layer 340 extend in the vertical direction (Z direction) and may be insulated from one another by the first insulation layer 340. The bottom surfaces of the plurality of bit line contacts BLC may contact the plurality of bit lines BL, respectively. The plurality of bit lines BL may extend penetrate through a second insulation layer 350 in the vertical direction (Z direction) and may be insulated from one another by the second insulation layer 350. The plurality of channel structures CHS may each be connected to a corresponding one bit line BL from among the plurality of bit lines BL through a bit line contact BLC.

A plurality of contact structures CNT may penetrate through the cover insulation layer 330 and the first insulation layer 340 and extend in the vertical direction (Z direction) on the connection region CON. The plurality of contact structures CNT may electrically connect the plurality of gate electrodes 321 and a plurality of wiring layers ML. For example, the top surfaces of the plurality of contact structures CNT may contact the plurality of gate electrodes 321, and the bottom surfaces of the plurality of contact structures CNT may contact the plurality of wiring layers ML. The plurality of wiring layers ML may penetrate through the second insulation layer 350 and extend in the vertical direction (Z direction) and may be insulated from one another by the second insulation layer 350. The bottom surfaces of the plurality of wiring layers ML may contact a plurality of first bonding vias 362. The plurality of first bonding vias 362 may penetrate through an interlayer insulation layer 360 and extend in the vertical direction (Z direction) and may be insulated from one another by the interlayer insulation layer 360. The bottom surface of a first bonding via 362 may contact the first bonding pad BP1.

From among the plurality of pass transistors TR, the pass transistors TR corresponding to the pass transistors TRa and TRb included in the integrated circuit devices 100, 100a, and 100b described above with reference to FIGS. 5 to 11 may be electrically connected to the plurality of gate electrodes 321 through the plurality of contact structures CNT. For example, the plurality of high-concentration source and drain regions 132a, 132b, and 132c (refer to FIG. 6) of the pass transistors TRa and TRb included in the integrated circuit devices 100, 100a, and 100b described above with reference to FIGS. 5 to 11 may be electrically connected to the plurality of gate electrodes 321 through the plurality of contact structures CNT and apply an operating voltage to the plurality of gate electrodes 321. According to some implementations, the plurality of high-concentration source and drain regions 132a, 132b, and 132c (refer to FIG. 6) of the pass transistors TRa and TRb (refer to FIG. 6) and the contact structures CNT corresponding to the plurality of high-concentration source and drain regions 132a, 132b, and 132c (refer to FIG. 6) may be electrically connected to each other through the peripheral circuit wiring structure 70, the second bonding vias 90, the second bonding pads BP2, the first bonding pads BP1, the first bonding vias 362, and the wiring layers ML. The peripheral circuit contacts 74 connected onto the plurality of high-concentration source and drain regions 132a, 132b, and 132c (refer to FIG. 6) of the plurality of pass transistors TRa and TRb may be the plurality of source and drain contacts 171a, 171b, and 171c shown in FIGS. 5 to 11.

Referring to FIG. 19, an integrated circuit device 400 may include the cell array structure CS and the peripheral circuit structure PS. Since components of the integrated circuit device 400 of FIG. 19 are similar to the components of the integrated circuit device 300 described above with reference to FIG. 18, descriptions below focus on the differences therebetween.

The peripheral circuit structure PS of the integrated circuit device 400 may be substantially identical or similar to the peripheral circuit structure PS of the integrated circuit device 300 described above with reference to FIG. 18.

The cell array structure CS may include the cell stack structure GS and a cell substrate 410 provided between the cell stack structure GS and the peripheral circuit structure PS. According to some implementations, the cell substrate 410 may include a semiconductor material, such as polysilicon.

The cell stack structure GS may be disposed on the cell substrate 410. The cell stack structure GS may include a plurality of gate electrodes 421 and a plurality of insulation layers 423 that are alternately arranged in the vertical direction. The cell stack structure GS may extend to have a shorter length in the first horizontal direction (X direction) on the connection region CON as it moves away from the peripheral circuit structure PS and the cell substrate 410. In other words, the cell stack structure GS may have a step-like shape. The cell stack structure GS may be covered by a cover insulation layer 430.

A plurality of channel structures CHS may penetrate through the cell stack structure GS and extend in the vertical direction (Z direction) on the memory cell region MEC. The configuration of the plurality of channel structures CHS may be substantially identical or similar to the configuration of the plurality of channel structures CHS described above with reference to FIG. 18.

According to some implementations, the plurality of channel structures CHS may be arranged to extend into the cell substrate 410. According to some implementations, the plurality of channel structures CHS may be arranged to contact the bottom surface of the cell substrate 410.

The top surfaces of the plurality of channel structures CHS may contact a plurality of bit line contacts BLC, respectively. The plurality of bit line contacts BLC may penetrate through a first insulation layer 440 extend in the vertical direction (Z direction) and may be insulated from one another by the first insulation layer 440. The top surfaces of the plurality of bit line contacts BLC may contact the plurality of bit lines BL, respectively. The plurality of bit lines BL may extend penetrate through a second insulation layer 450 in the vertical direction (Z direction) and may be insulated from one another by the second insulation layer 450. The plurality of channel structures CHS may each be connected to a corresponding one bit line BL from among the plurality of bit lines BL through a bit line contact BLC.

A plurality of contact structures CNT may penetrate through the cover insulation layer 430 and the first insulation layer 440 and extend in the vertical direction (Z direction) on the connection region CON. The top surfaces of the plurality of contact structures CNT may contact the plurality of wiring layers ML, respectively. The plurality of wiring layers ML may penetrate through the second insulation layer 450 and extend in the vertical direction (Z direction) and may be insulated from one another by the second insulation layer 450.

Through silicon vias TSV extend through the first insulation layer 440, the cover insulation layer 430, and the second interlayer insulation layer 162 in the vertical direction (Z direction) and may electrically connect the wiring layers ML and the peripheral circuit wiring layers 72. The through silicon vias TSV may be electrically connected to the plurality of gate electrodes 421 through the wiring layers ML and the contact structures CNT.

From among the plurality of peripheral circuit transistors TR, the pass transistors TR corresponding to the pass transistors TRa and TRb included in the integrated circuit devices 100, 100a, and 100b described above with reference to FIGS. 5 to 11 may be electrically connected to the plurality of gate electrodes 321 through the through silicon vias TSV, the wiring layers ML, and the contact structures CNT. For example, the plurality of high-concentration source and drain regions 132a, 132b, and 132c (refer to FIG. 6) of the pass transistors TRa and TRb included in the integrated circuit devices 100, 100a, and 100b described above with reference to FIGS. 5 to 11 may be electrically connected to the plurality of gate electrodes 321 through the through silicon vias TSV, the wiring layers ML, and the contact structures CNT and apply an operating voltage to the plurality of gate electrodes 321. According to some implementations, the high-concentration source and drain regions 132a, 132b, and 132c (refer to FIG. 6) of the pass transistors TRa and TRb (refer to FIG. 6) and the through silicon vias TSV corresponding to the high-concentration source and drain regions 132a, 132b, and 132c (refer to FIG. 6) may be electrically connected to each other through the peripheral circuit wiring structure 70. The peripheral circuit contacts 74 connected to the high-concentration source and drain regions 132a, 132b, and 132c of the pass transistors TRa and TRb (refer to FIG. 6) may be the plurality of source and drain contacts 171a, 171b, and 171c shown in FIGS. 5 to 11.

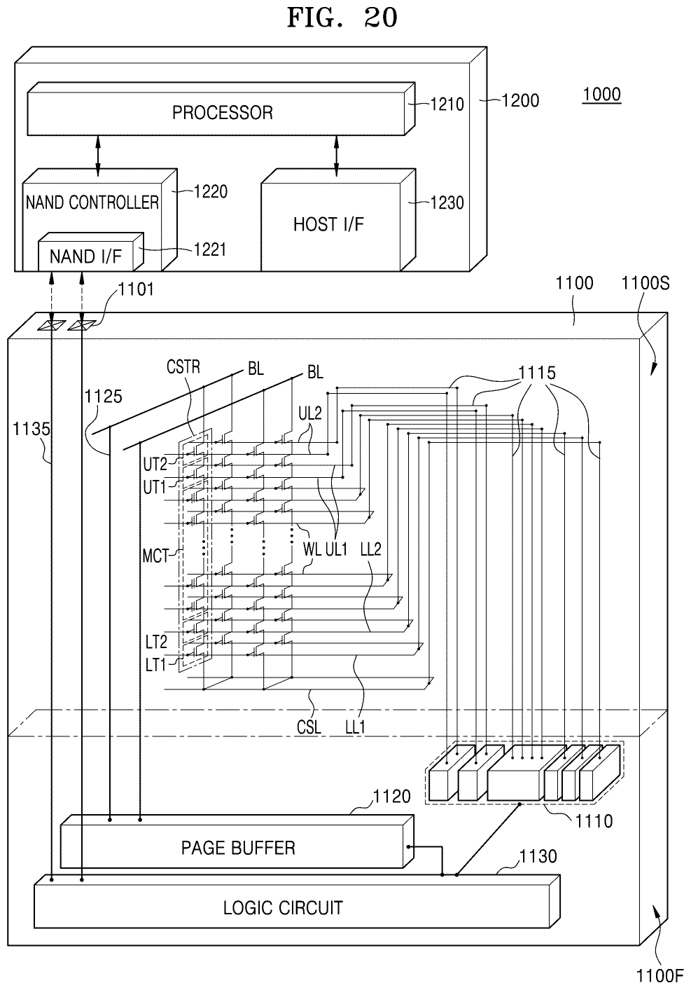

FIG. 20 is a schematic perspective view of an example of an electronic system 1000 including an integrated circuit element.

Referring to FIG. 20, the electronic system 1000 according to some implementations may include an integrated circuit device 1100 and a controller 1200 electrically connected to the integrated circuit device 1100. The electronic system 1000 may be a storage device including one or a plurality of integrated circuit devices 1100 or an electronic device including the storage device. For example, the electronic system 1000 may be a solid state drive (SSD) device, a universal serial bus (USB), a computing system, a medical device, or a communication device including at least one integrated circuit device 1100.

The integrated circuit device 1100 may be a non-volatile memory device. For example, the integrated circuit device 1100 may be a NAND flash memory device including at least one of the structures described above with respect to the integrated circuit devices 100, 100a, and 100b with reference to FIGS. 5 to 11. The integrated circuit device 1100 may include a first structure 1100F and a second structure 1100S on the first structure 1100F. According to some implementations, the first structure 1100F may also be disposed next to the second structure 1100S. The first structure 1100F may be a peripheral circuit structure including a decoder circuit 1110, a page buffer 1120, and a logic circuit 1130. The second structure 1100S may be a memory cell structure including the bit lines BL, the common source line CSL, the plurality of word lines WL, first and second gate upper lines UL1 and UL2, first and second gate lower lines LL1 and LL2, and a plurality of memory cell strings CSTR between the bit lines BL and the common source line CSL.

In the second structure 1100S, the plurality of memory cell strings CSTR may include lower transistors LT1 and LT2 adjacent to the common source line CSL, upper transistors UT1 and UT2 adjacent to the bit line BL, and a plurality of memory cell transistors MCT arranged between the lower transistors LT1 and LT2 and the upper transistors UT1 and UT2. The number of lower transistors LT1 and LT2 and the number of upper transistors UT1 and UT2 may be variously changed according to some implementations.

According to some implementations, the upper transistors UT1 and UT2 may include string select transistors, and the lower transistors LT1 and LT2 may include ground select transistors. The first and second gate lower lines LL1 and LL2 may be gate electrodes of the lower transistors LT1 and LT2, respectively. The word line WL may be a gate electrode of a memory cell transistor MCT, and the first and second gate upper lines L1 and UL2 may be gate electrodes of the upper transistors UT1 and UT2, respectively.

The common source line CSL, the first and second gate lower lines LL1 and LL2, the plurality of word lines WL, and the first and second gate upper lines UL1 and UL2 may be electrically connected to the decoder circuit 1110 through a plurality of first connection wires 1115 extending from the inside of the first structure 1100F to the second structure 1100S. The plurality of bit lines BL may be electrically connected to the page buffer 1120 through a plurality of second connection wires 1125 extending from the inside of the first structure 1100F to the second structure 1100S.

In the first structure 1100F, the decoder circuit 1110 and the page buffer 1120 may execute a control operation on at least one of the plurality of memory cell transistors MCT. The decoder circuit 1110 and the page buffer 1120 may be controlled by the logic circuit 1130.

The integrated circuit device 1100 may communicate with the controller 1200 through an input/output pad 1101 electrically connected to the logic circuit 1130. The input/output pad 1101 may be electrically connected to the logic circuit 1130 through an input/output connection wire 1135 extending from the inside of the first structure 1100F to the second structure 1100S.

The controller 1200 may include a processor 1210, a NAND controller 1220, and a host interface 1230. According to some implementations, the electronic system 1000 may include a plurality of integrated circuit devices 1100, and, in this case, the controller 1200 may control the plurality of integrated circuit devices 1100.

The processor 1210 may control the overall operation of the electronic system 1000 including the controller 1200. The processor 1210 may operate according to a certain firmware and may access the integrated circuit device 1100 by controlling the NAND controller 1220. The NAND controller 1220 may include a NAND interface 1221 that handles communication with the integrated circuit device 1100. Control commands for controlling the integrated circuit device 1100, data to be written to the memory cell transistors MCT of the integrated circuit device 1100, and data to be read from the memory cell transistors MCT of the integrated circuit device 1100 may be transmitted through the NAND interface 1221. The host interface 1230 may provide the function for communication between the electronic system 1000 and an external host. When a control command is received from an external host through the host interface 1230, the processor 1210 may control the integrated circuit device 1100 in response to the control command.

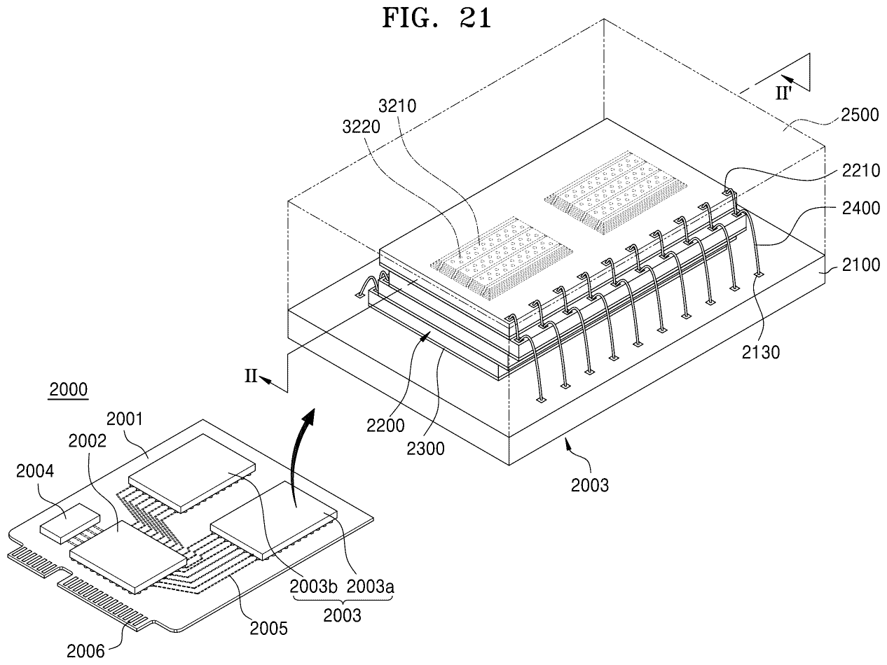

FIG. 21 is a schematic perspective view of an example of an electronic system 2000 including an integrated circuit device.

Referring to FIG. 21, the electronic system 2000 may include a main substrate 2001 and a controller 2002, one or more semiconductor packages 2003, and a DRAM 2004 that are mounted on the main substrate 2001. The semiconductor package 2003 and the DRAM 2004 may be connected to the controller 2002 by a plurality of wiring patterns 2005 formed on the main substrate 2001.

The main substrate 2001 may include a connector 2006 including a plurality of pins coupled to an external host. The number and arrangement of the pins of the connector 2006 may vary according to a communication interface between the electronic system 2000 and the external host. According to some implementations, the electronic system 2000 may communicate with an external host according to any one of interfaces including a universal serial bus (USB), peripheral component interconnect express (PCI-Express), serial advanced technology attachment (SATA), M-Phy for universal flash storage (UFS), etc. According to some implementations, the electronic system 2000 may operate by power supplied from an external host through the connector 2006. The electronic system 2000 may further include a power management integrated circuit (PMIC) that distributes power supplied from the external host to the controller 2002 and the semiconductor package 2003.

The controller 2002 may write data to or read data from the semiconductor package 2003 and may improve the operating speed of the electronic system 2000.

The DRAM 2004 may be a buffer memory for mitigating a speed difference between the semiconductor package 2003, which is a data storage space, and an external host. The DRAM 2004 included in the electronic system 2000 may also operate as a type of cache memory and may provide a space for temporarily storing data in a control operation for the semiconductor package 2003. When the DRAM 2004 is included in the electronic system 2000, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. The first and second semiconductor packages 2003a and 2003b may each be a semiconductor package including a plurality of semiconductor chips 2200. The first and second semiconductor packages 2003a and 2003b may each include a package substrate 2100, the semiconductor chips 2200 on the package substrate 2100, an adhesive layer 2300 disposed on the bottom surface of each of the semiconductor chips 2200, a connection structure 2400 electrically connecting the semiconductor chips 2200 and the package substrate 2100, and a molding layer 2500 covering the semiconductor chips 2200 and the connection structure 2400 on the package substrate 2100.

The package substrate 2100 may be a printed circuit board including a plurality of package upper pads 2130. The semiconductor chips 2200 may each include input/output pads 2210. The input/output pad 2210 may correspond to the input/output pad 1101 of FIG. 20. The plurality of semiconductor chips 2200 may each include a plurality of gate stacks 3210 and a plurality of channel structures 3220. The plurality of semiconductor chips 2200 may each include at least one of the structures described above with respect to the integrated circuit devices 100, 100a, and 100b with reference to FIGS. 5 to 11.

According to some implementations, the connection structure 2400 may be a bonding wire electrically connecting the input/output pad 2210 and the package upper pad 2130. Therefore, in the first and second semiconductor packages 2003a and 2003b, the semiconductor chips 2200 may be electrically connected to one another through bonding wires and may be electrically connected to the package upper pads 2130 of the package substrate 2100. According to some implementations, in the first and second semiconductor packages 2003a and 2003b, the semiconductor chips 2200 may be connected to one another through a connection structure including through silicon vias (TSVs) instead of the connection structure 2400 including bonding wires.

According to some implementations, the controller 2002 and the semiconductor chips 2200 may be included in one package. According to some implementations, the controller 2002 and the semiconductor chips 2200 may be mounted on a separate interposer substrate different from the main substrate 2001 and the controller 2002 and the semiconductor chips 2200 may be connected to each other through wires formed on the interposer substrate.

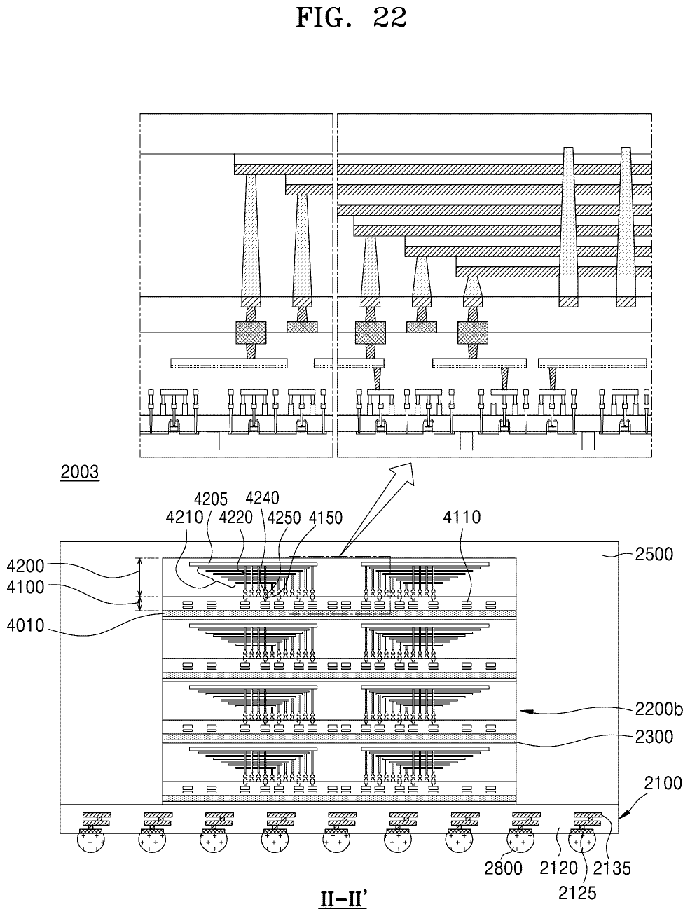

FIG. 22 is a schematic cross-sectional view of an example of a semiconductor package 2000. FIG. 22 shows a configuration along a line II-II′ of FIG. 21 in more detail.

Referring to FIG. 22, in a semiconductor package 2003, semiconductor chips 2200b may each include a semiconductor substrate 4010, a first structure 4100 on the semiconductor substrate 4010, and a second structure 4200 bonded onto the first structure 4100 by a wafer bonding method. The semiconductor chips 2200b may each include at least one of the structures described above with respect to the integrated circuit devices 100, 100a, and 100b with reference to FIGS. 5 to 11.

The first structure 4100 may include a peripheral circuit region including peripheral wires 4110 and first junction structures 4150. The second structure 4200 includes a common source line 4205, a gate stack structure 4210 between the common source line 4205 and the first structure 4100, memory channel structures 4220 penetrating through the gate stack structure 4210, and second junction structures 4250 electrically and respectively connected to the word lines WL (FIG. 20) of the memory channel structures 4220 and the gate stack structure 4210. For example, the second junction structures 4250 may be electrically connected to the memory channel structures 4220 and the word lines WL (FIG. 20) through bit lines 4240 electrically connected to the memory channel structures 4220 and gate connection wires electrically connected to the word lines WL (FIG. 20). First junction structures 4150 of the first structure 4100 and the second junction structures 4250 of the second structure 4200 may be bonded to each other while contacting each other. Bonded portions of the first junction structures 4150 and the second junction structures 4250 may include, for example, copper (Cu).

The semiconductor chips 2200b may further include the input/output pads 2210 (FIG. 21) electrically connected to the peripheral wires 4110 of the first structure 4100.

The semiconductor chips 2200 of FIG. 21 and the semiconductor chips 2200b of FIG. 22 may be electrically connected to each other through the plurality of connection structures 2400 in the form of bonding wires. However, according to some implementations, semiconductor chips in one semiconductor package, e.g., the semiconductor chips 2200 of FIG. 21 and the semiconductor chips 2200b of FIG. 22, may also be electrically connected to each other through a connection structure including the through silicon vias TSV.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been shown and described with reference to implementations thereof, it will be understood that various changes in form and details may be made therein without departing from the spirit and scope of the following claims.

What is claimed is:

1. An integrated circuit device comprising:
a substrate comprising an active region and a plurality of source and drain doped regions, the plurality of source and drain doped regions located within the active region and spaced apart from each other in a first horizontal direction;
a gate structure disposed between the plurality of source and drain doped regions on the substrate and extending in a second horizontal direction, the second horizontal direction intersecting the first horizontal direction; and
a multilayer wiring structure comprising a source and drain contact, a gate contact, a first wiring layer, and a second wiring layer, the source and drain contact connected to the plurality of source and drain doped regions, the gate contact connected to the gate structure, the first wiring layer connected to an upper portion of the source and drain contact, and the second wiring layer disposed between the source and drain contact and the gate contact and spaced apart from the first wiring layer,
wherein a length of the second wiring layer in a vertical direction is greater than a length of the first wiring layer in the vertical direction.

2. The integrated circuit device of claim 1, wherein the second wiring layer extends from a side of the gate structure in the second horizontal direction, and wherein the second wiring layer vertically overlaps a portion of the plurality of source and drain doped regions.

3. The integrated circuit device of claim 1, comprising:
a third wiring layer connected to an upper end of the gate contact;
a first peripheral circuit contact connected to an upper end of the second wiring layer;
a second peripheral circuit contact connected to an upper end of the third wiring layer; and
a fourth wiring layer connected to an upper end of the first peripheral circuit contact and an upper end of the second peripheral circuit contact,
wherein the second wiring layer is configured to be electrically connected to the gate contact through the first peripheral circuit contact, the fourth wiring layer, the second peripheral circuit contact, and the third wiring layer.

4. The integrated circuit device of claim 3, wherein a length of the fourth wiring layer in the first horizontal direction is greater than a length of the fourth wiring layer in the vertical direction.

5. The integrated circuit device of claim 1, comprising:
a protective film that covers the plurality of source and drain doped regions and the gate structure on the substrate; and
an etch stop film disposed over the substrate at a vertical level higher than ta vertical level of the protective film and extending in the first horizontal direction,
wherein the source and drain contact extends through the etch stop film in the vertical direction, and
wherein a bottom surface of the second wiring layer contacts a top surface of the etch stop film.

6. The integrated circuit device of claim 1, comprising:
a protective film that covers the plurality of source and drain doped regions and the gate structure on the substrate; and
an etch stop film extending in the first horizontal direction over the substrate and disposed at a vertical level lower than a vertical level of a topmost surface of the protective film,
wherein the source and drain contact extends through the etch stop film in the vertical direction, and
wherein a bottom surface of the second wiring layer contacts a top surface of the etch stop film.

7. The integrated circuit device of claim 1, wherein a length of the second wiring layer in the vertical direction is greater than a length of the second wiring layer in the first horizontal direction.

8. The integrated circuit device of claim 1, wherein, in a plan view, the active region has a rectangular shape of which a length in the first horizontal direction is greater than a length of the active region in the second horizontal direction.

9. The integrated circuit device of claim 1, comprising a plurality of first wiring layers and a plurality of second wiring layers are provided, wherein the plurality of first wiring layers and the plurality of second wiring layers are alternately positioned in the first horizontal direction.

10. The integrated circuit device of claim 1, wherein a top surface of the first wiring layer and a top surface of the second wiring layer are located on a same plane.

11. The integrated circuit device of claim 1, wherein a bottom surface of the second wiring layer is at a lower level than a bottom surface of the first wiring layer.

12. An integrated circuit device comprising:
a substrate comprising a device isolation region, an active region located within the device isolation region, a plurality of low-concentration source and drain doped regions located within the active region and spaced apart from one another in a first horizontal direction, and a plurality of high-concentration source and drain doped regions located inside the plurality of low-concentration source and drain doped regions, the plurality of high-concentration source and drain doped regions being more densely doped than the plurality of low-concentration source and drain doped regions;
a gate structure disposed between the plurality of low-concentration source and drain doped regions on the substrate and extending in a second horizontal direction, the second horizontal direction perpendicular to the first horizontal direction;
an etch stop film extending in the first horizontal direction over the substrate; and
a multilayer wiring structure comprising a source and drain contact, a gate contact, a first wiring layer, a second wiring layer, a first peripheral circuit contact, a third wiring layer, a second peripheral circuit contact, and a fourth wiring layer, the source and drain contact connected to a high-concentration source and drain doped region, the gate contact connected to the gate structure, the first wiring layer connected to an upper end of the source and drain contact, the second wiring layer disposed at a location vertically overlapping a portion of a low-concentration source and drain doped region, the first peripheral circuit contact connected to an upper end of the second wiring layer, the third wiring layer connected to an upper end of the gate contact, the second peripheral circuit contact connected to an upper end of the third wiring layer, and the fourth wiring layer connected to an upper end of the first peripheral circuit contact and an upper end of the second peripheral circuit contact,
wherein a length of the second wiring layer in a vertical direction is greater than a length of the first wiring layer in the vertical direction.

13. The integrated circuit device of claim 12, wherein a length of the second wiring layer in the second horizontal direction is greater than a length of the second wiring layer in the first horizontal direction.

14. The integrated circuit device of claim 12, wherein, in a plan view, the second wiring layer is located between the gate structure and the source and drain contact.

15. The integrated circuit device of claim 12, wherein the active region comprises:
a pair of base active regions extending in the first horizontal direction and spaced apart from each other in the second horizontal direction; and
a center active region integrated with the pair of base active regions and extending in the second horizontal direction between the pair of base active regions,
wherein a width of the center active region in the first horizontal direction is less than a width of each base active region of the pair of base active regions in the first horizontal direction, and
wherein a high-concentration source and drain doped region of the plurality of high-concentration source and drain doped regions is located in the center active region.

16. The integrated circuit device of claim 12, comprising a protective film that covers the plurality of low-concentration source and drain doped regions and the gate structure on the substrate,
wherein a top surface of the protective film is further away from the substrate in the vertical direction than a top surface of the etch stop film.

17. The integrated circuit device of claim 12, comprising a protective film that covers the plurality of low-concentration source and drain doped regions and the gate structure on the substrate,
wherein a top surface of the protective film is closer to the substrate in the vertical direction than a top surface of the etch stop film.

18. The integrated circuit device of claim 12, wherein the source and drain contact, the gate contact, the first peripheral circuit contact, the second peripheral circuit contact, the first wiring layer, the second wiring layer, the third wiring layer, and the fourth wiring layer comprise a same material.

19. An electronic system comprising:
a main substrate;
a cell stacked structure comprising a peripheral circuit structure and a cell array structure, wherein the cell array structure comprises a plurality of gate electrodes and a plurality of insulation layers, the plurality of gate electrodes and the plurality of insulation layers overlap the peripheral circuit structure in a vertical direction and are alternately stacked, and the cell stacked structure has a step-like shape; and
a controller electrically connected to the peripheral circuit structure on the main substrate,
wherein the peripheral circuit structure comprises:
a substrate comprising a device isolation region, an active region located within the device isolation region, a plurality of low-concentration source and drain doped regions located within the active region and spaced apart from one another in a first horizontal direction, and a plurality of high-concentration source and drain doped regions located inside the plurality of low-concentration source and drain doped regions, the plurality of high-concentration source and drain doped regions being more densely doped than the plurality of low-concentration source and drain doped regions;
a gate structure disposed between the plurality of low-concentration source and drain doped regions on the substrate and extending in a second horizontal direction, the second horizontal direction perpendicular to the first horizontal direction;
an etch stop film extending in the first horizontal direction over the substrate; and
a multilayer wiring structure comprising a source and drain contact, a gate contact, a first wiring layer, a second wiring layer, a first peripheral circuit contact, a third wiring layer, a second peripheral circuit contact, and a fourth wiring layer, the source and drain contact connected to a high-concentration source and drain doped region, the gate contact connected to the gate structure, the first wiring layer connected to an upper end of the source and drain contact, the second wiring layer connected to the etch stop film, the first peripheral circuit contact connected to an upper end of the second wiring layer, the third wiring layer connected to an upper end of the gate contact, the second peripheral circuit contact connected to an upper end of the third wiring layer, and the fourth wiring layer connected to an upper end of the first peripheral circuit contact and an upper end of the second peripheral circuit contact, and
wherein a length of the second wiring layer in the vertical direction is greater than a length of the first wiring layer in the vertical direction.

20. The electronic system of claim 19, wherein the active region comprises:
a pair of base active regions extending in the first horizontal direction and spaced apart from each other in the second horizontal direction; and
a center active region integrated with the pair of base active regions and extending in the second horizontal direction between the pair of base active regions,
wherein a width of the center active region in the first horizontal direction is less than a width of each base active region of the pair of base active regions in the first horizontal direction, and
wherein a high-concentration source and drain doped region of the plurality of high-concentration source and drain doped regions is located in the center active region.
